(19) United States
(12) Patent Application Publication
(10) Pub. No.: US 2015/0325278 A1
(43) Pub. Date: Nov. 12, 2015

(54) VOLTAGE-CONTROLLED SOLID-STATE MAGNETIC DEVICES

(71) Applicants: Uwe Bauer, Cambridge, MA (US); Geoffrey S.D. Beach, Winchester, MA (US)

(72) Inventors: Uwe Bauer, Cambridge, MA (US); Geoffrey S.D. Beach, Winchester, MA (US)

(21) Appl. No.: 14/659,059

(22) Filed: Mar. 16, 2015

Related U.S. Application Data
(60) Provisional application No. 61/953,677, filed on Mar. 14, 2014.

(51) Int. Cl. G11C 11/16; H01L 43/08; H01L 43/10; H01L 43/02

(52) U.S. Cl. CPC G11C 11/161; G11C 11/1675; H01L 43/02; H01L 43/08; H01L 43/10

(57) ABSTRACT

Systems, methods, and apparatus are provided for tuning a functional property of a device. The device includes a layer of a dielectric material disposed over and forming an interface with a layer of an electrically conductive material. The dielectric material layer includes at least one ionic species having a high ion mobility. The electrically conductive material is configured such that a potential difference applied to the device can cause the at least one ionic species to migrate reversibly across the interface into or out of the electrically conductive material layer.

### CROSS-REFERENCES TO RELATED APPLICATIONS

This application claims priority to U.S. provisional application Ser. No. 61/953,689,” filed on Mar. 14, 2014, entitled “METHODS, MATERIALS AND SYSTEMS FOR VOLTAGE PROGRAMMING MATERIAL PROPERTIES,” which is hereby incorporated herein by reference in its entirety.

### GOVERNMENT SUPPORT

This invention was made at least in part using government support under contract nos. ECCS-1128439 and DMR-0819762, both awarded by the National Science Foundation (NSF). The government has certain rights in the invention.

### BACKGROUND

There has been a great deal of interest in magnetic devices. Magnetic devices function based on the capability of generating different patterns of magnetization in a magnetizable material in a non-volatile manner.

In an example magnetic devices, the magnetization of a cell of the magnetic device may be controlled using a magnetic field that interacts with the magnetizable material. The orientation of the magnetization can affect the resistance of portions of the magnetizable material forming the cell. Thus, for a given applied voltage, a cell with the magnetization oriented in one direction may exhibit a different resistance than if the magnetization were oriented in a different direction. As a result, the magnetizable material can be used, e.g., to store data, through changes in the magnetization direction.

Another example of a magnetic device is a magnetic tunnel junction (MTJ) device having large tunnel magneto-resistance, such as in MTJs with MgO tunnel barriers. The interest in these devices stems from the large tunnel magneto-resistance combined with their inherently non-volatile characteristics, which causes them to be considered a candidate for next generation non-volatile memory applications such as magnetic random access memory (MRAM).

In many of these proposed MTJ based magnetic memory devices, such as field switched MRAM and spin transfer torque MRAM, significant current flow is necessary to switch the magnetic free layer and therefore the state of the device. The main challenge for such devices lies in reducing the current flow necessary to manipulate the magnetization in MTJs.

Using a gate voltage to assist switching of the free layer in a MTJ could significantly lower the current necessary to switch the device state. Moreover, voltage control in MTJs would simultaneously provide compatibility with voltage based semiconductor technology. Indeed, several mechanisms have been proposed to allow voltage-assisted switching in MTJs. Those mechanisms include: electric field control of magnetic anisotropy in ferromagnetic (FM) metal/dielectric bilayers, voltage control of magnetic anisotropy in strain-coupled FM metal/ferroelectric bilayers, mechanical stress mediated magneto-electric coupling in piezoelectric/magnetostrictive bilayers, and voltage control of the exchange field in FM metal/multiferroic bilayers.

Based on those mechanisms, a number of device concepts have been proposed to reduce the switching current in MTJs. These device concepts can be separated into two categories based on the location of the voltage-controlled layer within the MTJ stack. FIG. 1A shows an example of a typical device structure for the first device category, in which the tunnel barrier also provides the voltage induced functionality. See, e.g., U.S. Publication No. 2013/0015542 A1 to Wang et al. FIG. 1B shows an example of a typical device structure for the second device category, where a dedicated layer adjacent to the magnetic free layer is used to provide the voltage functionality. See, e.g., U.S. Publication No. 2010/0080048 A1 to Liu et al.

The example device structure of FIG. 1A includes an ordered insulator (element I in FIG. 1A) that serves as the gate dielectric. The ordered insulator can be magnesium oxide. The gate dielectric layer simultaneously acts as the tunnel barrier between the pinned magnetic layer and the free magnetic layer in the MTJ stack (elements M1 and M2 of FIG. 1A). The gate dielectric layer therefore needs to exhibit high tunneling magneto-resistance, as well as strong voltage induced effects. The dual function of the tunnel barrier therefore often results in conflicting design criteria for device optimization.

The second device category avoids this complication by separating the voltage-control functionality from the tunnel barrier. This can be achieved by adding a separate voltage-controlled layer (see element P in FIG. 1B) adjacent to the free magnetic layer (see element M3 in FIG. 1B) in the MTJ stack. The voltage-controlled layer here is made up of a piezoelectric, ferroelectric or multiferroic materials. Those materials often suffer from a loss of functionality at room temperature, degradation during operation and challenging processing conditions.

The present disclosure provides novel devices that facilitate greater voltage control of magnetic anisotropy, magnetization, and other device properties.

### SUMMARY

The Inventors have recognized and appreciated that a dynamically control a wide range of functional properties of a solid state device would be beneficial. In view of the foregoing, various embodiments are directed generally to methods, apparatus, and systems for controlling magnetic anisotropy, and consequently the orientation of the magnetization vector, of a magnetic device using electrical voltage. Example devices herein include a dielectric material layer disposed in an x-y plane, and a ferromagnetic material layer over and forming an interface with the dielectric material layer. The dielectric material layer includes at least one ionic species having a high ion mobility. The ferromagnetic material is configured to reversibly uptake an amount of the at least one ionic species of the dielectric material layer.

Example systems, methods, and apparatus are provided that facilitate local modification of magnetic anisotropy to control the velocity of magnetic domain walls propagating in the ferromagnetic material layer. Domain wall pinning sites can be generated in selected regions of the example device, to locally pin magnetic domain walls. The example devices can be configured to control the location where magnetic domains nucleate and where domain wall pinning sites can be generated.

In an example where the device includes metal/dielectric heterostructures, rich chemical, electronic, magnetic and mechanical properties can be derived through the controlling and regulation of interfacial chemistry and structure.

The example methods, apparatus, and systems include means for optically irradiating and/or heating (or cooling) a spatial region of the example device, and means for applying a potential difference in a direction across the interface between the dielectric material layer and the ferromagnetic material layer. The example methods, apparatus, and systems include applying the potential difference for a duration of time sufficient to modify a proportionate amount of the at least one ionic species in a portion of the electrically conductive material proximate to the interface, thereby causing a change of the functional property of the device.

Example systems, methods, and apparatus are provided to generate a domain wall pinning site in an example device. The example device includes a ferromagnetic material layer, a gate oxide dielectric layer disposed over the ferromagnetic material layer, and a gate electrode layer disposed over, and in electrical communication with, the gate oxide dielectric material layer. The lateral dimension of the gate oxide dielectric layer is approximately equal to the lateral dimension of the gate electrode layer. The gate electrode layer, the gate oxide dielectric layer, and the ferromagnetic material layer are configured such that a first potential difference applied in a first direction between the gate electrode layer and the ferromagnetic material layer generates a domain wall pinning site at a region of the ferromagnetic material layer, and a second potential difference applied in a second direction, opposite to the first direction, between the gate electrode layer and the ferromagnetic material layer substantially eliminates the domain wall pinning site.

Example systems, methods, and apparatus are provided to generate a change in the magnetic anisotropy at a portion of an example device. The example device includes a ferromagnetic material layer, a gate oxide dielectric layer disposed over the ferromagnetic material layer, and a gate electrode layer disposed over, and in electrical communication with, the gate oxide dielectric material layer. The lateral dimension of the gate electrode layer is smaller than the lateral dimension of the gate oxide dielectric layer. The gate electrode layer, the gate oxide dielectric layer, and the ferromagnetic material layer are configured such that a first potential difference applied in a first direction between the gate electrode layer and the ferromagnetic material layer generates a change in the magnetic anisotropy at a portion of the ferromagnetic material layer proximate to the portion of the gate oxide dielectric layer that is proximate to the gate electrode layer.

Example systems, methods, and apparatus are provided to regulate the proportionate amount of the oxide ions in a portion of a target layer to cause a change in the magnetic anisotropy of a ferromagnetic material layer of an example device. The example device includes a first ferromagnetic material layer, a tunnel barrier layer disposed over the first ferromagnetic material layer, a second ferromagnetic material layer disposed over the first ferromagnetic material layer, a gate oxide dielectric layer disposed over the second ferromagnetic material layer, the gate oxide dielectric layer having high oxide ion mobility, and a gate electrode layer disposed over, and in electrical communication with, the gate oxide dielectric material layer. The second ferromagnetic material layer is configured to reversibly uptake an amount of the oxide ions. The gate electrode layer, the gate oxide dielectric layer, and the second ferromagnetic material layer are configured such that a first potential difference applied in a first direction generates a change in the proportionate amount of the oxide ions in a portion of the target layer, thereby causing a change in the magnetic anisotropy of the second ferromagnetic material layer.

Example systems, methods, and apparatus are provided to program information to an example device. The example device includes a ferromagnetic material layer disposed in an x-y plane, a gate oxide dielectric layer disposed over the ferromagnetic material layer, and a gate electrode layer disposed over, and in electrical communication with, the gate oxide dielectric material layer. The lateral dimension of the ferromagnetic material layer is greater than the lateral dimensions of the gate oxide dielectric layer and the gate electrode layer. An example method to program information to an example device includes nucleating a magnetic domain wall at a region of the ferromagnetic material layer, applying a first magnetic field having a first polarity to the device, and applying a potential difference between the gate electrode layer and the ferromagnetic material layer. The gate electrode layer, the gate oxide dielectric layer, and the ferromagnetic material layer are configured such that the potential difference applied in a first direction between the gate electrode layer and the ferromagnetic material layer generates a domain wall pinning site at a region of the ferromagnetic material layer, and the potential difference applied in a second direction, opposite to the first direction, between the gate electrode layer and the ferromagnetic material layer substantially eliminates the domain wall pinning site.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIGS. 1A-1B show example magnetic tunnel junction (MTJ) devices, according to principles of the present disclosure.

FIGS. 2A-2C show an schematic representation of an example device structure, according to principles of the present disclosure.

FIGS. 3A-3F show the cross section of example devices, according to principles of the present disclosure.

FIGS. 4A and 4B illustrate two different cross-sectional geometries of an example two-terminal configurations, according to principles of the present disclosure.

FIG. 4C illustrates an example three-terminal configuration, according to principles of the present disclosure.

FIGS. 5A and 4B illustrate example two-dimensional arrays, according to principles of the present disclosure.

FIG. 5C illustrates an example three-dimensional, multi-layer array, according to principles of the present disclosure.

FIGS. 6A and 6B show example modified MTJ-devices, according to principles of the present disclosure.

FIGS. 7A-7E show a schematic of an example measurement apparatus and example magnetic hysteresis loops, according to principles of the present disclosure.

FIGS. 8A-8D shows examples of measured space- and time-resolved domain expansion, according to principles of the present disclosure.

FIGS. 9A-9G show examples of control of domain wall propagation in magnetic nanostrip conduits, according to principles of the present disclosure.

FIGS. 10A-10E shows example measurement results of the properties of domain wall traps in nanostrip conduits, according to principles of the present disclosure.

FIGS. 11A-11K show an example device, according to principles of the present disclosure.

FIG. 12A shows an example device and measurement setup, according to principles of the present disclosure.

FIGS. 12B-12E show example maps of H_{c} around gate electrode on the example device of FIG. 12A, according to principles of the present disclosure.

FIG. 13 shows example measurement results of mean magnetization reversal time as a function of position, according to principles of the present disclosure.

FIG. 14A-14B shown an example of trapping high velocity domain walls, according to principles of the present disclosure.

FIGS. 15A-15L shows an example of the anisotropy modification and physical electrode degradation in high voltage regime, according to principles of the present disclosure.

FIGS. 16A-16F shows example voltage effects under local illumination, according to principles of the present disclosure.

### DETAILED DESCRIPTION

Following below are more detailed descriptions of various concepts related to, and embodiments of, inventive systems, methods and apparatus for voltage-controlled solid-state magnetic devices. It should be appreciated that various concepts introduced above and described in greater detail below may be implemented in any of numerous ways, as the disclosed concepts are not limited to any particular manner of implementation. Examples of specific implementations and applications are provided primarily for illustrative purposes.

As used herein, the term “includes” means includes but is not limited to, the term “including” means including but not limited to. The term “based on” means based at least in part on.

With respect to layers, substrates or other surfaces described herein in connection with various examples of the principles herein, any references to “top” surface and “bottom” surface are used primarily to indicate relative position, alignment and/or orientation of various elements/components with respect to the substrate and each other, and these terms do not necessarily indicate any particular frame of reference (e.g., a gravitational frame of reference). Thus, reference to a “bottom” of a substrate or a layer does not necessarily require that the indicated surface or layer be facing a ground surface. Similarly, terms such as “over,” “under,” “above,” “beneath,” “underneath” and the like do not necessarily indicate any particular frame of reference, such as a gravitational frame of reference, but rather are used primarily to indicate relative position, alignment and/or orientation of various elements/components with respect to the substrate or layer (or other surface) and each other. The terms “disposed on” and “disposed over” encompass the meaning of “embedded in,” including “partially embedded in.” In addition, reference to feature A being “disposed on,” “disposed between,” or “disposed over” feature B encompasses examples where feature A is in contact with feature B, as well as examples where other layers and/or other components are positioned between feature A and feature B.

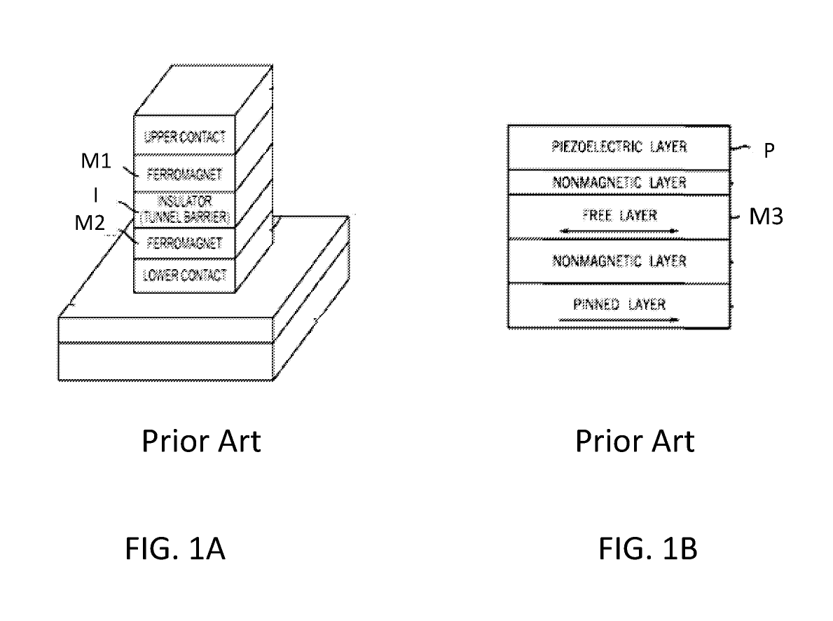

An example device of this disclosure herein is different from the first device category in that the example device herein uses a specified layer configured for the voltage functionality. The voltage functionality is provided by a solid state ionic conductor (SSIC) placed adjacent to the magnetic free layer of an example device. This SSIC is also a dielectric material (also referred to herein in various examples as a gate dielectric or a gate oxide dielectric), across which an electrical potential difference can be applied. Depending on bias polarity of the applied potential difference, as well as the charge of the mobile ionic species, a voltage applied across the SSIC results in transport of ionic species to or away from the interface between the SSIC and the magnetic free layer. Accumulation or depletion of the mobile ionic species modifies the chemical coordination at this interface, which results in a change in the interfacial magnetic anisotropy of the magnetic free layer. A reduction in magnetic anisotropy or saturation magnetization of the magnetic free layer results in a reduction of its energy barrier for switching and consequently the magnetization of the free layer can be manipulated by a lower current flow. The mechanism exploited herein, based on voltage control of interfacial chemistry, is entirely different from the mechanisms of the devices in FIGS. 1A-1B. With its temperature stability and simple processing requirements, the example systems, methods, and apparatus herein alleviate some of the challenges of the second device category (FIG. 1B).

In example systems, apparatus, and methods herein, the layer that provides the voltage functionality is throughout understood to be a dielectric material that acts as a solid state ionic conductor. As described in greater detail hereinbelow, the dielectric material can be any high-k dielectric material with high mobility ionic species.

Example systems, methods and apparatus are provided herein that facilitate use of a voltage to control magnetic anisotropy in ferromagnetic metal thin films and nanodevices. Magnetic anisotropy is a key property of magnetic materials because it controls the two quantities that facilitate successful integration of magnetic materials into practical applications such as information storage and information processing. First, magnetic anisotropy determines the orientation of the easy magnetization axis of a magnetic material, i.e., the axis along which the magnetization vector is preferentially aligned, and second it determines the energy necessary to switch the magnetization vector from an orientation that is parallel to an orientation that is anti-parallel along this easy magnetization axis. Since in magnetic devices, such as but not limited to magnetic data storage devices, information is encoded in the orientation of the magnetization vector, control of its preferred axis of orientation and the energy necessary to switch it from a parallel to an antiparallel orientation are exploited herein to realize magnetic memory devices.

Example systems, methods and apparatus are provided herein that facilitate use of a voltage to control the saturation magnetization in ferromagnetic metal thin films and nanodevices. The saturation magnetization describes the total magnetic moment per unit volume in the material in the magnetically saturated state (that is, when the magnetization is uniformly oriented in the material). In the context of a magnetic memory element, the torque to be applied to a magnetic material to switch its magnetization direction depends on the saturation magnetization and the total magnetic moment of the material. Moreover, the local magnetic energy in a material depends on the saturation magnetization, so that local variations in the saturation magnetization can create pinning sites for magnetic domain walls.

Example systems, methods and apparatus are provided herein that facilitate use of a voltage to control the magnetic permeability of the example device. Using the example systems, methods, and apparatus herein, the change of proportionate amount of the at least one ionic species in a portion of the ferromagnetic material layer can be used to vary at least one of: (i) the magnetic anisotropy, (ii) the magnetization, and (iii) the magnetic moment of the film, thereby modifying the magnetic permeability of the target layer.

In a non-limiting example, the magnetic properties of the example device can be modified such that the example device operates in a linear response region, where the magnetization is approximately proportional to the applied magnetic field.

The example systems, methods and apparatus herein facilitate electrical control of magnetism, thereby paving the way for revolutionary new spintronic devices, many of which rely on efficient manipulation of magnetic domain walls in ferromagnetic nanostructures (such as but not limited to nanostrips, also referred to herein as nanowire conduits). According to the principles herein, regulation of voltage-induced charge accumulation at a metal-oxide interface can be used to influence domain wall motion in ultrathin metallic ferromagnets. According to the principles herein, an applied voltage can be used to generate non-volatile switching of magnetic properties at the nanoscale by modulating interfacial chemistry rather than charge density. Using a solid-state ionic conductor as a gate dielectric, strong voltage-controlled domain wall traps can be generated to function as non-volatile, electrically programmable and switchable magnetic domain wall pinning sites. Sufficiently high pinning strengths can be readily achieved to bring to a standstill propagating magnetic domain walls, e.g., magnetic domain walls travelling at speeds of at least about 20 ms⁻¹. Example systems, methods and apparatus herein provide example devices that exhibit this novel magneto-ionic effect, to demonstrate non-volatile memory devices in which voltage-controlled domain wall traps facilitate electrical bit selection in a magnetic material (such as but not limited to a ferromagnetic material film, or a nanostrip register).

Magnetic anisotropy also plays a role in magnetic domain wall motion and dynamics. A magnetic domain wall refers to the interface between two oppositely magnetized areas of a magnetic material. Because of their small dimensions, which can be on the nanometer scale, and their ability to encode magnetic information, magnetic domain walls form the basis of many magnetic devices which are currently proposed or under development. Modifications in magnetic anisotropy can be used to modulate the width and elastic energy of a magnetic domain wall. They can also be used to control the dynamics and motion of a magnetic domain wall in a magnetic thin film or nano device. Local modification of magnetic anisotropy can be used to control the domain wall velocity, it can be used to locally pin magnetic domain walls, and it can be used to control the location where magnetic domains nucleate (i.e., nucleation sites). These capabilities can be exploited for next generation magnetic devices based on domain wall motion.

Magnetic anisotropy in ultrathin metallic ferromagnets also can be tuned by an electric field, opening the door to ferromagnetic field-effect devices in which a gate voltage can control the magnetic state. Magnetoelectric coupling in metals has, until now, been achieved by charging up a ferromagnetic thin film, which acts as one plate of a capacitor. Electron accumulation or depletion of the ferromagnet can alter its magnetic properties. Since the charge density of a metal can be varied only slightly, the change in magnetic anisotropy energy can be small. This mechanism can be used to modulate domain wall velocity in nanometer-thick cobalt films, where the effect could be detected in the slower, thermally activated creep regime (μm s−1 to mm s−1) where velocity is exponentially sensitive to surface anisotropy. Some practical applications may require the manipulation of domain walls travelling at tens to hundreds of meters per second.

Since the example devices and methods described herein for controlling magnetic anisotropy, and consequently the orientation of the magnetization vector, exploit electrical voltage rather than magnetic fields or electrical currents, they benefit from the inherently lower power consumption of voltage-controlled processes. Similarly, controlling magnetic properties by voltage has the added benefit of being compatible with existing semiconductor technologies such as complementary metal oxide semiconductor logic which is also voltage based. The here described method for voltage controlled magnetic properties is different from other methods of voltage control of magnetic anisotropy by exploiting an ionic intermediary to control magnetic anisotropy. In the example device designs according to the principles herein, an oxide dielectric layer simultaneously acts as a solid state ionic conductor. The oxide dielectric can be placed adjacent to the ferromagnetic metal film and, under an applied gate voltage, oxygen ions inside the oxide layer can be moved to or away from the ferromagnetic metal layer. Since magnetic anisotropy in the ferromagnetic metal can be very sensitive to the oxygen ion concentration in the ferromagnetic material proximate to its interface with the oxide dielectric, using a gate voltage to move oxygen ions to or away from this interface then allows voltage control of magnetic anisotropy and magnetization at the interface.

Many existing devices are configured to prevent, or significantly reduce the possibility of, migration of ionic species from the dielectric material layer to an adjacent electrically conductive layer. The migration of ionic species into any portion of an adjacent electrically conductive layer can be a breakdown mechanism of a device, such as a shorting. For example, diffusion barriers may be used in these devices to prevent such ionic species migration. As another example, the ferromagnetic material layer can be formed from a conductive material that is not conducive to ionic species migration, or that reduces or prevents the ionic species migration in normal operation (such as noble metals). The electrically conductive layer could also be made of other conducting material that do not strongly interact or react with the mobile ionic species in the dielectric material layer. In some cases, one of the terminals of the device could be replaced with a conductor in close proximity to the device multilayer structure, such as the tip of a scanning probe microscope.

Applicants have developed example devices, and systems, methods and apparatus incorporating such example devices, that exploit the reversible migration of ionic species from a dielectric material layer to an adjacent ferromagnetic material layer to regulate the magnetic anisotropy and saturation magnetization of portions of the device. In some examples, the device can be configured to generate magnetic domain wall pinning sites at specified regions.

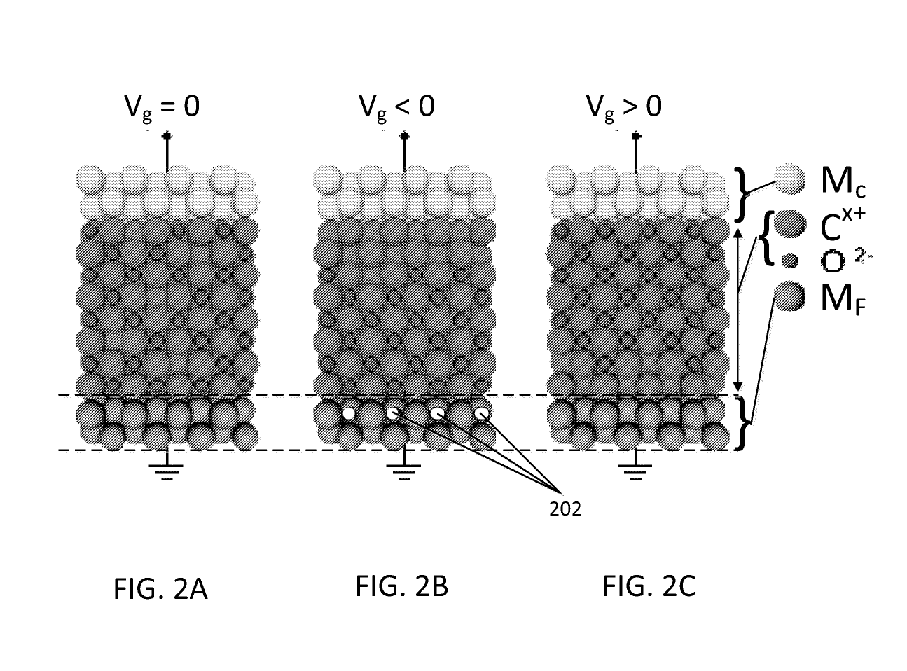

FIG. 2A-2C is an example schematic representation of an example device structure and oxygen ion motion in the device under differing gate voltages (positive and negative gave voltages). The example device of FIG. 2A includes a ferromagnetic material layer (M_{F}) that forms an interface with a dielectric material layer. The example dielectric material layer includes cations (C^{x+}) and oxide ions (O²⁻). The example device includes a gate electrode layer (M_{C}), which can include a noble metal, a transition metal, or any other conductive material as described herein. As shown in FIG. 2B, with a non-zero potential difference applied in a first direction (a negative bias, V_{g}<0), an amount of the oxide ions (indicated at 202) migrates into portions of the ferromagnetic material layer (M_{F}) proximate to the interface. That is, the negative bias moves oxygen ions towards the ferromagnetic material-oxide interface in this example. As shown in FIG. 2C, with a non-zero potential difference applied in a second direction that is opposite the first direction (a positive bias, V_{g}>0), the oxide ions that had migrated into portions of the ferromagnetic material layer (M_{F}) are returned to the dielectric material layer. The positive bias moves ions away from the interface. Accordingly, FIGS. 2A-2C illustrate the reversible migration of the ionic species from a dielectric material layer to the adjacent ferromagnetic material layer of an example device.

In an example device according to the principles herein, the ferromagnetic material layer is kept sufficiently thin, such that the magnetic anisotropy of the ferromagnetic material films in the ferromagnetic material-dielectric oxide material bilayer is sensitive to the oxygen stoichiometry at the interface. The dielectric oxide material used is a high-k dielectric and an oxygen ion conductor with high oxygen vacancy mobility. In an example device, the ferromagnetic material shows strong perpendicular magnetic anisotropy (i.e., an easy magnetization axis perpendicular to the film plane) for a given desired oxygen stoichiometry at the ferromagnetic material-dielectric oxide material interface. If the interface is over oxidized, or under-oxidized, the perpendicular magnetic anisotropy is lost and the system develops an easy axis in the plane of the ferromagnetic material film plane. Application of a gate voltage across the interface results in motion of oxygen ions in the dielectric oxide material layer. This in turn modifies the oxygen stoichiometry at the ferromagnetic material-dielectric oxide material interface, and therefore changes the magnetic anisotropy in the ferromagnetic material film. For example, as illustrated in FIGS. 2A-2C, under a gate voltage in a first direction, oxygen ions move away from the ferromagnetic material-dielectric oxide material interface. Under a gate voltage of an opposite bias, the oxygen ions migrate towards the ferromagnetic material-dielectric oxide material interface. The modification of magnetic anisotropy in the ferromagnetic material film is then determined by the oxygen stoichiometry at the ferromagnetic material-dielectric oxide material interface and the polarity of the gate voltage.

In any example device herein, the ferromagnetic material layer can have a thickness of about 0.5 nm, about 0.7 nm, about 0.9 nm, about 1 nm, about 1.3 nm, about 1.5 nm, about 1.8 nm, or greater. The dielectric material layer can have a thickness of about 1.0 nm, about 2.0 nm, about 3.0 nm, about 5.0 nm, 7.0 nm, about 9.0 nm, about 10 nm, about 13 nm, about 15 nm, about 20 nm, about 25 nm, about 30 nm, about 35 nm, about 40 nm or greater. References to thickness of a layer are to the magnitudes in the z-direction.

The perpendicular magnetic anisotropy in the ferromagnetic material-dielectric oxide material bilayers derives from the interfacial hybridization between the ferromagnetic material and the mobile ionic species. Changes to the interfacial hybridization state can have a pronounced impact on the perpendicular magnetic anisotropy. As a non-limiting example, in an example device that includes a Co/metal-oxide bilayer, the perpendicular magnetic anisotropy derives from the Co—O interfacial hybridization, and slight changes to the interfacial oxidation state have a pronounced impact on the perpendicular magnetic anisotropy. According to the principles herein, an example device is configured with a gate oxide dielectric having high ionic mobility, such that electrical displacement of the O²⁻ ion at the ferromagnetic material-dielectric oxide material interface can be used to tune the anisotropy, and even to remove and reintroduce its very source. The effects described herein do not rely on maintaining an electrical charge, therefore, the voltage-induced changes to magnetic properties persist at zero bias, enabling non-volatile switching and state retention in the power-off state. The example systems, methods, and apparatus provide for the merging nanoionics and nanomagnetics into novel ‘magneto-ionic’ devices. They provide an attractive alternative to magnetoelectric composites, which rely on complex oxides (piezoelectrics or ferroelectrics) to achieve similar functionality.

As a non-limiting example, regulating the magnetic anisotropy of portions of the device can include reversibly controlling the change of proportionate amount of the at least one ionic species in a portion of the ferromagnetic layer of the example device to cause a change between a perpendicular magnetic anisotropy to a state of zero or nearly zero magnetic anisotropy at the portion of the device. This provides an example of a two-state system that can be used to store data. According to the principles herein, an example device can be patterned with regions of differing magnetic anisotropy (perpendicular vs. zero magnetic anisotropy), thereby programming data to the example device.

As another non-limiting example, regulating the magnetic anisotropy of portions of the device can include controlling the change of proportionate amount of the at least one ionic species in a portion of the ferromagnetic layer of the example device to cause a change between a perpendicular (out-of-plane) magnetic anisotropy and an in-plane magnetic anisotropy at the portion of the device. This provides another example of a two-state system that can be used to store data. According to the principles herein, an example device can be patterned with regions of differing magnetic anisotropy (perpendicular vs. in-plane magnetic anisotropy), thereby programming data to the example device.

As yet another non-limiting example, regulating the magnetic anisotropy of portions of the device can include controlling the change of proportionate amount of the at least one ionic species in a portion of the ferromagnetic layer of the example device to cause a change among a perpendicular (out-of-plane) magnetic anisotropy, an in-plane magnetic anisotropy, and zero magnetic anisotropy, at the portion of the device. This provides an example of a three-state system that can be used to store substantially more data.

The functional property of the magnetic anisotropy of the target layer can be regulated based on the example systems, methods, and apparatus described herein for controlling and regulating the migration of the ionic species into the target layer. Using the example systems, methods, and apparatus herein, the regulation of the proportionate amount of the at least one ionic species in a portion of the first layer can be used to cause a change between a metastable state of the target layer having perpendicular (out-of-plane) magnetic anisotropy and a metastable state of the target layer having an in-plane magnetic anisotropy. In another example, the regulation of the proportionate amount of the at least one ionic species in a portion of the first layer can be used to cause a change between a metastable state of the target layer having zero or nearly zero magnetic anisotropy. A read-out of the device can be based on detection of the magnetic anisotropy of each discrete site of differing magnetic anisotropy. This capability can be exploited to provide magnetic devices, such as but not limited to a magnetic memory device, by using these differing metastable states to program information. Accordingly, the example systems, methods, and apparatus herein can provide a magnetic device that is based on use of two of these metastable states (e.g., as “1” and “0”), or all three of these metastable states, for programming information based on any computer logic, logic theory or stochastic theory.

In an example, the local magnetic anisotropy state can also be determined by monitoring the motion of a magnetic domain wall. In a non-limiting example, the gate electrode can be configured to reversible create a local domain wall pinning site by locally modifying the magnetic anisotropy. The ease with which a magnetic domain wall can propagate in the vicinity of the gate electrode depends on the local magnetic properties.

The example devices, systems, methods, and apparatus according to the principles herein can be configured as a spintronic device, a magnetic recording device, a memristor, a non-volatile memory device, a magnetoresistive random-access memory device, a voltage-controlled magnetic memory, an electrically controllable catalysis device, a voltage controlled optical switch, a flash drive, an electrically erasable programmable read-only memory, a solid-state drive, a dynamic random-access memory, a static random-access memory, a responsive window tinting device, or a display device.

The example devices, systems, methods, and apparatus according to the principles herein can be used to provide memristors for implementation in applications such as, but not limited to, nanoelectronic memories, computer logic, and neuromorphic/neuromemristive computer architectures. As non-limiting examples, the devices, systems, methods, and apparatus according to the principles herein can be configured to provide non-volatile computer memory and storage, flash drives, including EEPROMs (electrically erasable programmable read-only memory), solid-state drives (SSD), dynamic random-access memory (DRAM), and Static random-access memory (SRAM). The example device elements can be used in applications using different types of memory, such as but not limited to, capacitor, variable capacitor, floating gate transistor, four transistor feedback loop circuit, or magnetic tunnel junction in commercialized DRAM, FeRAM, NOR flash, SRAM or MRAM, technologies. The novel devices, systems, methods, and apparatus according to the principles herein can be used to removable storage devices for mobile devices and smartphones, cameras, tablets, and other portable applications.

An example devices according to the principles herein includes a dielectric material layer disposed in an x-y plane, and an ferromagnetic material layer over and forming an interface with the dielectric material layer. The dielectric material layer includes at least one ionic species having a high ion mobility. The ferromagnetic material is configured to reversibly uptake an amount of the at least one ionic species. Non-limiting example dielectrics include any high-k dielectric oxide, oxynitride, silicate, or other oxygen-containing dielectric with high oxygen ion mobility.

In a non-limiting example implementation, the example ferromagnetic material layer forms an interface with a dielectric material layer that includes oxide ions species. The modification of the proportionate amount of the oxide ions species in a portion of the ferromagnetic material layer causes a change in magnetic anisotropy of the device. As described herein, the modification of the proportionate amount of the at least one ionic species in the ferromagnetic material layer proximate to the interface causes a change in magnetic anisotropy of the example device. In an example, a magnetic memory/storage device can be derived based on selectively and controllably causing local changes to the magnetic anisotropy of different spatial regions of the example device, thereby programming bits of data (information) into different spatial regions of the example device.

In operation, under the directional influence of an applied potential difference in a direction across the interface between the dielectric material layer and the ferromagnetic material layer, the at least one ionic species are caused to migrate into (or out of) the portions of the ferromagnetic material layer proximate to the interface. That is, the potential difference is applied for a duration of time sufficient to cause a change in the proportionate amount of the at least one ionic species present in the portions of the ferromagnetic material layer proximate to the interface. Due to the nanoscale thickness of the ferromagnetic material layer, changes to the proportionate composition at the interface can affect the materials properties of the ferromagnetic material layer. Accordingly, the dielectric material layer serves as a reservoir of the ionic species. Migration of the ionic species into or out of the ferromagnetic material proximate to the interface facilitates tuning of the materials properties of the ferromagnetic material layer. This facilitates tuning of the magnetic anisotropy property(ies) of portions of the example device.

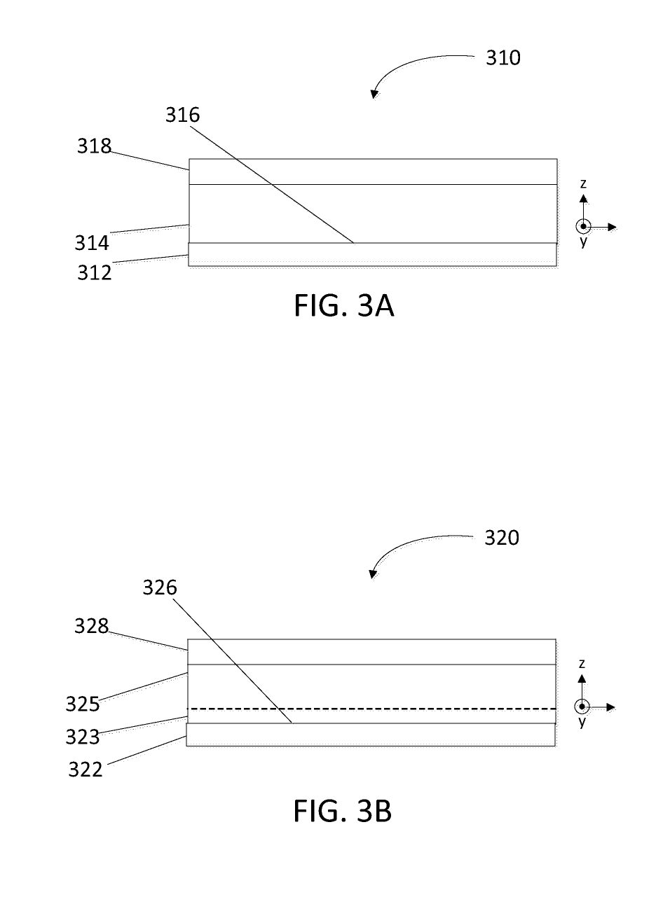

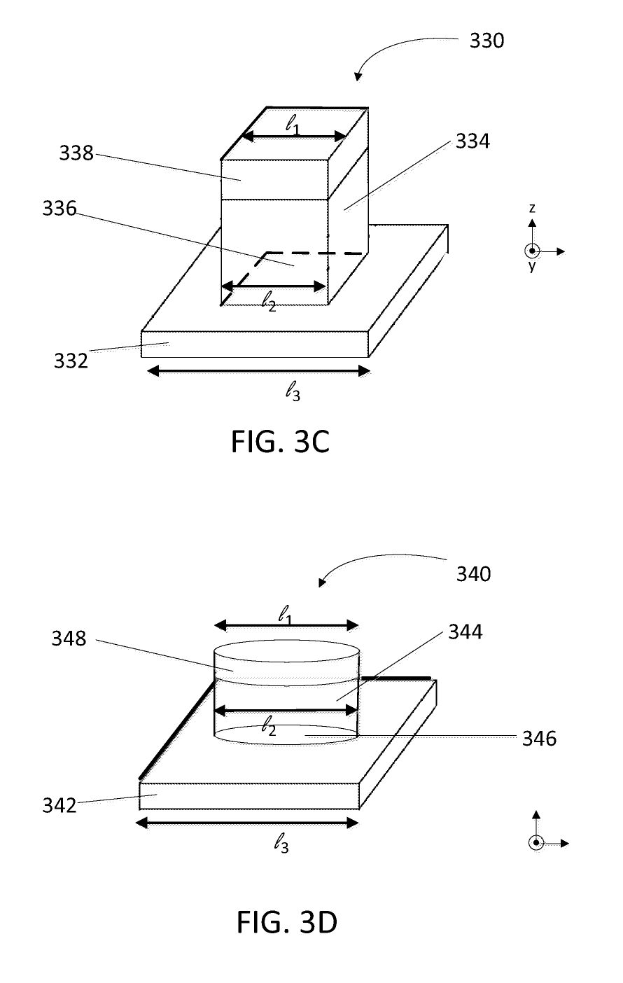

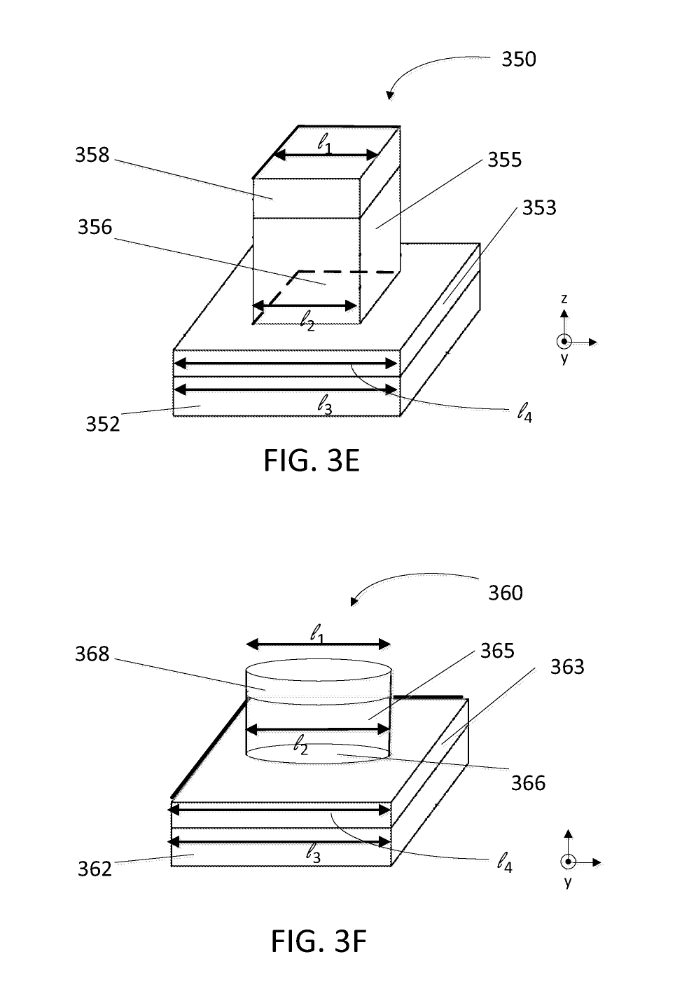

FIG. 3A shows the cross section of another example device 310 according to the principles of the instant disclosure. The example device 310 includes an electrically conductive material layer 312 formed from a ferromagnetic material, and a dielectric material layer 314 disposed in an x-y plane, as a gate oxide dielectric layer. As shown in FIG. 3C, the electrically conductive material layer 312 forms an interface 316 with the dielectric material layer 314. Example device 310 also includes a gate electrode layer 318 disposed over, and in electrical communication, with the dielectric material layer 314 (as a gate oxide dielectric layer).

FIG. 3B shows the cross section of another example device 320 according to the principles of the instant disclosure. The example device 320 includes an electrically conductive material layer 322 formed from a ferromagnetic material disposed in an x-y plane, and a bilayer of dielectric material formed as an intermediate oxide dielectric layer 323 and a gate oxide dielectric layer 325. As shown in FIG. 3C, the electrically conductive material layer 322 forms an interface 326 with the intermediate oxide dielectric layer 323. Example device 320 includes a gate electrode layer 328 in electrical communication with the gate oxide dielectric layer 325.

FIG. 3C shows an example device 330 according to the principles of the instant disclosure. The example device 330 includes an electrically conductive material layer 332 formed from a ferromagnetic material disposed in an x-y plane, and a dielectric material layer 334 disposed in an x-y plane, as a gate oxide dielectric layer. As shown in FIG. 3C, the electrically conductive material layer 332 forms an interface 336 with the gate oxide dielectric layer 334. Example device 330 includes a gate electrode layer 338 in electrical communication with the gate oxide dielectric layer 335. As shown in example device 330, the gate oxide dielectric layer 334 and the gate electrode layer 338 can each have a substantially rectangular or square cross-section.

FIG. 3D shows an example device 340 according to the principles of the instant disclosure. The example device 340 includes an electrically conductive material layer 342 formed from a ferromagnetic material disposed in an x-y plane, and a dielectric material layer 344 disposed in an x-y plane, as a gate oxide dielectric layer. As shown in FIG. 3D, the electrically conductive material layer 342 forms an interface 346 with the gate oxide dielectric layer 344. Example device 340 includes a gate electrode layer 348 in electrical communication with the gate oxide dielectric layer 345. As shown in example device 340, the gate oxide dielectric layer 344 and the gate electrode layer 348 can each have a substantially elliptical, or circular cross-section. In other non-limiting examples, the gate oxide dielectric layer 334 and the gate electrode layer 338 can each have any other polygonal cross-sections, such as but not limited to a hexagonal cross-section, or an elliptical or circular cross section.

In the non-limiting examples of FIGS. 3C and 3D, the lateral dimension l₂ of the gate oxide dielectric layer is approximately equal to the lateral dimension l₁ of the gate electrode layer. In these examples, the lateral dimension l₃ of the ferromagnetic material layer is greater than the lateral dimensions l₁ and l₂. In other non-limiting example devices, the lateral dimension l₁ of the gate electrode layer can be smaller than the lateral dimension of the gate oxide dielectric layer l₂.

FIG. 3E shows an example device 350 according to the principles of the instant disclosure. The example device 350 includes an electrically conductive material layer 352 formed from a ferromagnetic material disposed in an x-y plane, and a bilayer of dielectric material formed as an intermediate oxide dielectric layer 353 and a gate oxide dielectric layer 355. As shown in FIG. 3E, the electrically conductive material layer 352 forms an interface 356 with the intermediate oxide dielectric layer 353. Example device 350 includes a gate electrode layer 358 in electrical communication with the gate oxide dielectric layer 355.

FIG. 3F shows an example device 360 according to the principles of the instant disclosure. The example device 360 includes an electrically conductive material layer 362 formed from a ferromagnetic material disposed in an x-y plane, and a bilayer of dielectric material formed as an intermediate oxide dielectric layer 363 and a gate oxide dielectric layer 365. As shown in FIG. 3F, the electrically conductive material layer 362 forms an interface 366 with the intermediate oxide dielectric layer 363. Example device 360 includes a gate electrode layer 368 in electrical communication with the gate oxide dielectric layer 365.

As shown in the non-limiting examples of FIGS. 3E and 3F, the gate oxide dielectric layer and the gate electrode layer can have a substantially rectangular or square cross-section (FIG. 3E) or a substantially elliptical, or circular cross-section (FIG. 3F). In another example, the gate oxide dielectric layer and the gate electrode layer can each be formed with other polygonal cross-sections, such as but not limited to a hexagonal cross-section. As also shown in the non-limiting examples of FIGS. 3E and 3F, the lateral dimension l₂ of the gate oxide dielectric layer is approximately equal to the lateral dimension l₁ of the gate electrode layer. In these example, the lateral dimension l₃ of the ferromagnetic material layer and the intermediate oxide dielectric layer l₄ are greater than the lateral dimensions l₁ and l₂. In other non-limiting example devices, the lateral dimension l₁ of the gate electrode layer can be smaller than the lateral dimension of the gate oxide dielectric layer l₂.

In the non-limiting examples of FIGS. 3E and 3F, the intermediate oxide dielectric layer and the ferromagnetic material layer are shown as having similar lateral dimensions (l₃≈l₄). In other examples, the intermediate oxide dielectric layer and the ferromagnetic material layer can be configured to have different lateral dimensions (l₃≠l₄). For example, the example device can be fabricated such that the ferromagnetic material layer has a greater lateral dimension than the intermediate oxide dielectric layer (l₃<l₄).

In various example implementations according to the principles herein, including the example devices of any of FIGS. 3B, 3E and 3F, the gate oxide dielectric layer can be configured with a greater thickness in the z-direction than the intermediate oxide dielectric material layer, by a factor of about 2, about 3, about 5, about 10, or higher. In some examples, the intermediate oxide dielectric layer can be formed from a different dielectric material than the gate oxide dielectric layer.

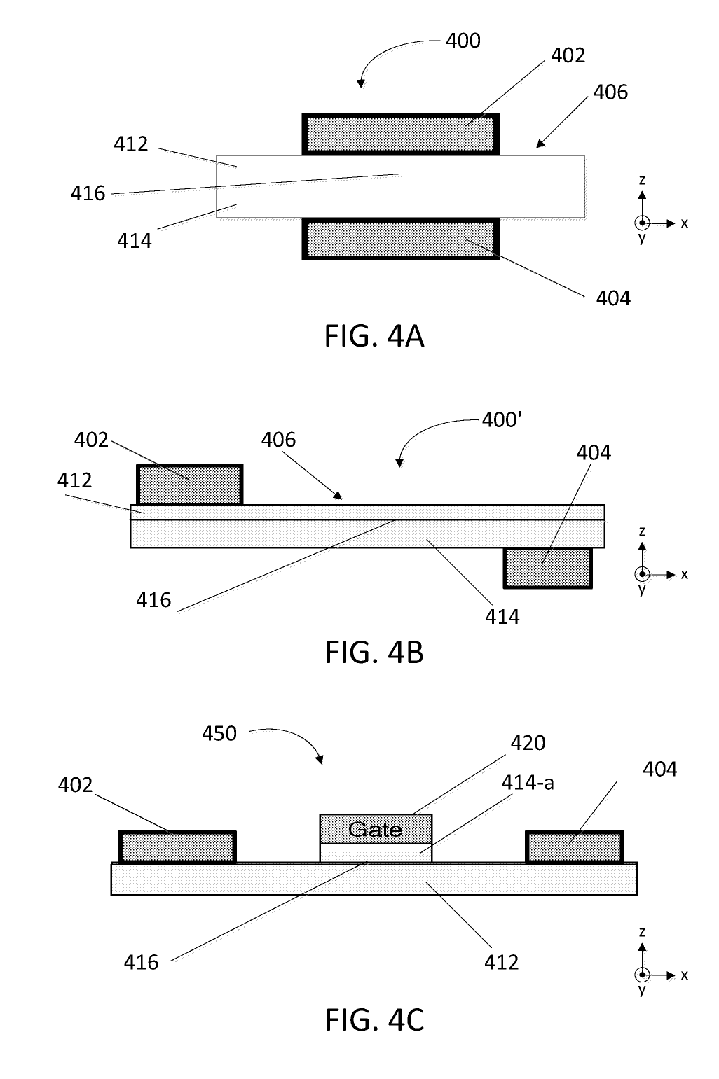

In various example implementations according to the principles herein, including the example devices of any of FIGS. 3A through 3F, any of the example devices according to the principles herein may be configured in a two-terminal configuration, a three-terminal configuration (illustrated in FIGS. 4A-4C).

FIGS. 4A and 4B illustrate two different cross-sectional geometries of non-limiting example two-terminal configurations 400 and 400′. Both FIGS. 4A and 4B show example two-terminal configuration that include electrically conductive contacts 402 and 404 coupled in electrical communication with opposite sides of example device 406 in the z-direction. In accordance with the principles described herein, example devices 406 include a ferromagnetic material layer 412 that forms an interface 416 with a dielectric material layer 414. In different examples according to the principles herein, the dielectric material layer 414 can be a gate oxide dielectric layer, or the dielectric material layer 414 can be a bilayer formed between an intermediate oxide dielectric layer and a gate oxide dielectric layer (where interface 416 is formed with the intermediate oxide dielectric layer). In the example two-terminal configuration 400 of FIG. 4A, the electrically conductive contacts 402 and 404 are disposed to overlap each other. In the example two-terminal configuration 400′ of FIG. 4B, the electrically conductive contacts 402 and 404 are disposed to have no overlap. The non-limiting examples of FIGS. 4A and 4B are shown with the ferromagnetic material layer 412 and the dielectric material layer 414 having similar lateral dimensions. In other non-limiting examples, the ferromagnetic material layer 412 and the dielectric material layer 414 can have different lateral dimensions, such as described herein in connection with FIGS. 3D-3F. Furthermore, in an example where the dielectric material layer 414 is a bilayer formed between an intermediate oxide dielectric layer and a gate oxide dielectric layer, these two layers can have differing lateral dimensions relative to each other.

An example device and method of controlling magnetic anisotropy by mean of an electrical voltage can implement the following device configuration: a two-terminal device that includes three functional layers. A thin ferromagnetic metal layer can be used as one of the two electrodes of the device. The ferromagnetic metal layer provides the medium in which information is encoded through the orientation of the magnetization vector. Non-limiting example ferromagnetic materials that can be used include cobalt (Co), nickel (Ni), iron (Fe), a ferromagnetic alloy of any one or more of these metals, or a ferromagnetic alloy including any one or more of these elements as well as at least one of boron (B), carbon (C), copper (Cu), hafnium (Hf), palladium (Pd), platinum (Pt), rhenium (Re), rhodium (Rh), or ruthenium (Ru). Adjacent to the ferromagnetic metal layer is a dielectric which simultaneously acts as a solid state ionic conductor. Non-limiting example dielectrics include any high-k dielectric oxide, oxynitride, silicate, or other oxygen-containing dielectric with high oxygen ion mobility. As an example, the oxide dielectric can be, but is not limited to, an oxide, oxynitride, or silicate of gadolinium (Gd), tantalum (Ta), zirconium (Zr), hafnium (Hf), or other transition metal or rare earth metal. The function of the dielectric layer is twofold. First, the dielectric layer controls the magnetic anisotropy in the ferromagnetic metal layer through the chemical composition at the interface between the two layers. Second, the dielectric layer blocks the flow of electronic carries but is a good conductor of the ionic species which control the magnetic anisotropy of the ferromagnetic metal at the dielectric material/ferromagnetic metal interface. Next to the dielectric layer is a conductive layer (such as a non-magnetic metal layer or a magnetic metal layer) that acts as a gate electrode and forms the second terminal of the device. In an example, the gate electrode can be made from a noble metal to avoid the occurrence of electrochemical reactions at this electrode. In other examples, the gate electrode can be formed from any electrically conductive material, such as but not limited to a transition metal, a doped semiconductor, a transparent conductive oxide, a group III-V conductive material, or aluminum. In another example, additional terminals can be added for other functionalities, in addition to the two terminals, such as for flowing current along the ferromagnetic layer, or for measuring resistance states.

With a sufficiently high gate voltage applied between the gate electrode and the ferromagnetic metal layer, the resulting electric field in the dielectric layer acts to move the ionic species of interest either to or away from the ferromagnetic metal/dielectric interface. The direction of ionic motion is determined by the charge of the ionic species and the polarity of the applied voltage. Since the magnetic anisotropy of the ferromagnetic layer is determined by the presence of the ionic species of interest at the ferromagnetic metal/dielectric interface, moving those species to or away from this interface then allows voltage control of the magnetic anisotropy in the ferromagnetic film.

FIG. 4C illustrates a non-limiting example three-terminal configuration 450. The example three-terminal configuration includes electrically conductive contacts 402 and 404 coupled in electrical communication with electrically conductive material layer 412. One side of the dielectric material layer 414-a forms an interface 416 with the electrically conductive material layer 412. A gate electrode 420 is disposed over the other side of the dielectric material layer 414-a. In different examples according to the principles herein, the dielectric material layer 414-a can be a gate oxide dielectric layer, or the dielectric material layer 414-a can be a bilayer formed between an intermediate oxide dielectric layer and a gate oxide dielectric layer (where interface 416 is formed with the intermediate oxide dielectric layer). In this example according to the principles herein, the example device 406 includes a dielectric material layer 414-a that forms an interface 416 with only a portion of the electrically conductive material layer 412. In the example of FIG. 4C, electrically conductive contacts 402 and 404 are disposed on the same side of electrically conductive material layer 412. In another example according to the principles herein, electrically conductive contacts 402 and 404 can be disposed on opposite sides of electrically conductive material layer 412.

In the various example devices and configurations according to the principles herein, including the example devices of any of FIGS. 3A through 3F or the device configurations of any of FIGS. 4A through 4C, the gate electrode layer, the gate oxide dielectric layer, and the ferromagnetic material layer can be configured such that magnetic domain wall pinning sites can be generated in portions of the example device using an applied potential difference.

In any example device, including the example devices of any of FIGS. 3A through 3F or the device configurations of any of FIGS. 4A through 4C, the gate dielectric layer and/or the intermediate oxide layer can be formed as an amorphous material or a semi-crystalline material. Using an amorphous material or a semi-crystalline material, and providing a high-diffusivity path for ionic exchange, the magnetic anisotropy or other magnetic property can be toggled at the nanoscale. For example, this can facilitate creation of voltage-controlled domain wall traps with unprecedented pinning strength.

In any example herein, including the example devices of any of FIGS. 3A through 3F or the device configurations of any of FIGS. 4A through 4C, the example device can configured such that the domain wall pinning site is non-volatile, and persists after the applied voltage is discontinued for a period of time. For example, the example device can configured such that, after the applied voltage is discontinued, the domain wall pinning site persists for about 10 nanoseconds, about 100 nanoseconds, about 500 nanoseconds, about 1 microsecond, about 500 microseconds, about 1 millisecond, about 100 milliseconds, about 500 milliseconds, about 1 second, about 5 seconds, about 10 seconds, about 30 seconds, about 60 seconds, about 3 minutes, about 5 minutes, about 10 minutes, about 30 minutes, about 60 minutes, for several hours, for several days, or longer much periods of time.

The novel device design according to the principles herein, including the example devices of any of FIGS. 3A through 3F or the device configurations of any of FIGS. 4A through 4C, allows voltage induced changes to the oxygen stoichiometry of ferromagnetic material layer proximate to the interface between the ferromagnetic material layer and the oxide dielectric layer, at temperatures as low as room temperature and at higher temperatures. The changes in oxygen stoichiometry result in a strong modification of magnetic anisotropy of the ferromagnetic material layer. Since ionic motion occurs efficiently along the open oxide edge generated based on the device configurations according to the principles described herein, the changes in magnetic anisotropy can occur at the immediate area of the ferromagnetic material layer underneath the oxide dielectric material layer edge. Moreover, at a given gate voltage, oxygen ions accumulate over time in the ferromagnetic material layer proximate to the interface, so the local degree of magnetic anisotropy modification can be controlled by the bias dwell time. In addition, the rate of oxygen ion motion depends on the amplitude of the gate voltage, so that at a give bias dwell time, the local degree of magnetic anisotropy modification can be controlled by the amplitude of the applied bias voltage. Different combinations of bias voltage amplitude and dwell time can be used to control the total change in oxygen stoichiometry of the ferromagnetic layer, and therefore the change in magnetic anisotropy.

According to the principles herein, an example device can be configured such that the lateral dimension of the gate oxide dielectric can be larger than the lateral dimensions of the gate electrode. A potential difference applied in a first direction between the gate electrode layer and the ferromagnetic material layer generates a change in the magnetic anisotropy at a surface of the ferromagnetic material layer proximate to the portion of the gate oxide dielectric layer that is under the gate electrode layer. In this example, the materials of the oxide dielectric and the gate electrode are configured to allow for sufficiently high oxygen mobility to and from the interface to facilitate local control of the oxygen stoichiometry at the interface of the ferromagnetic material and the oxide dielectric. This example device can exploit a domain wall pinning effect at various points throughout the bulk as well as near an edge as described herein.

The spatial confinement of ionic motion that can be derived based on the device configurations according to the principles described herein, including the example devices of any of FIGS. 3A through 3F or the device configurations of any of FIGS. 4A through 4C, results in the creation of very sharp and deep wells in the magnetic anisotropy energy landscape of the ferromagnetic material layer. These can act as the magnetic domain wall pinning sites that trap passing magnetic domain walls. Specifically, the example device according to the principles described herein are configured such that, with application of a potential difference across the interface between the gate electrode layer and the ferromagnetic material layer, one or more magnetic domain walls that are propagating across regions of the ferromagnetic material layer can be pinned at or near a region below the gate electrode layer. The example devices of any of FIGS. 3A through 3F or the device configurations of any of FIGS. 4A through 4C, can include at least one domain wall nucleating component to nucleate at least one domain wall at a region of the ferromagnetic material layer that is not in an overlap region between the gate electrode layer and the ferromagnetic material layer, and/or at a region of the ferromagnetic material layer that is in the overlap region. The one or more magnetic domain walls can be nucleated at a portion of the ferromagnetic material layer using any technique, such as but not limited to applying a mechanical stress, or applying a voltage, proximate to the portion of the ferromagnetic layer. Accordingly, this example devices and device configurations facilitate the creation of voltage programmable domain wall pinning sites that can be set to any desired pinning strength and that can be implemented to stop magnetic domain walls at precise locations.

In an example implementation, the gate oxide dielectric layer, and the ferromagnetic material layer can be configured such that a first potential difference applied in a first direction between the gate electrode layer and the ferromagnetic material layer generates a magnetic domain wall pinning site at a region of the ferromagnetic material layer. A potential difference applied in a second direction, opposite to the first direction, between the gate electrode layer and the ferromagnetic material layer substantially eliminates the magnetic domain wall pinning site.

In example implementations, the devices and device configurations can be configured such that the lateral dimension of the gate oxide dielectric, the lateral dimension of the gate electrode, and the lateral dimension of the ferromagnetic material layer can be approximately equal to each other. A potential difference applied in a first direction between the gate electrode layer and the ferromagnetic material layer generates a change in the magnetic anisotropy at a surface of the ferromagnetic material layer proximate to the portion of the gate oxide dielectric layer that is under the gate electrode layer.

In an example, the change in the magnetic anisotropy of the ferromagnetic material layer can be an increase, or a reduction, of the perpendicular magnetic anisotropy.

In an example, the change in magnetic anisotropy may accompany a change in the saturation magnetization of the ferromagnetic material.

In an example, the change in the magnetic anisotropy of the ferromagnetic material layer can be of a magnetization axis in the plane of the ferromagnetic material layer.

In example implementations, the gate electrode layer, the gate oxide dielectric layer, and the ferromagnetic material layer can be configured such that a first potential difference applied in a first direction between the gate electrode layer and the ferromagnetic material layer generates a change in the magnetic anisotropy at a portion of the ferromagnetic material layer proximate to the portion of the gate oxide dielectric layer that is proximate to the gate electrode layer.

In example implementations, the devices and device configurations can be configured such that the ferromagnetic material layer, including the ferromagnetic material layer of any of FIGS. 3A through 3F or any of FIGS. 4A through 4C, can have a longitudinal conformation. For example, the ferromagnetic material layer can include at least one nanostrip. A nanostrip can be configured as a portion of the ferromagnetic material layer that is formed as a longitudinal structure. For example, the nanostrip can be configured to have a rectangular cross-section. The nanostrip can have a length to width aspect ratio of at least about 3:2 (i.e., length/width≈1.5), or higher. For example, the aspect ratio can be about 5:1, about 10:1, about 100:1, about 1000:1, or higher. The nanostrip can have a width on the order of nanometers, such as but not limited to about 3 nm, about 5 nm, 10 nm, about 25 nm, or about 50 nm. The thickness of the nanostrip in the z-direction can be less than the width of the nanostrip. In an example, the ferromagnetic material layer can include two or more nanostrips. In various examples herein, the nanostrip is also referred to as a nanowire conduit.

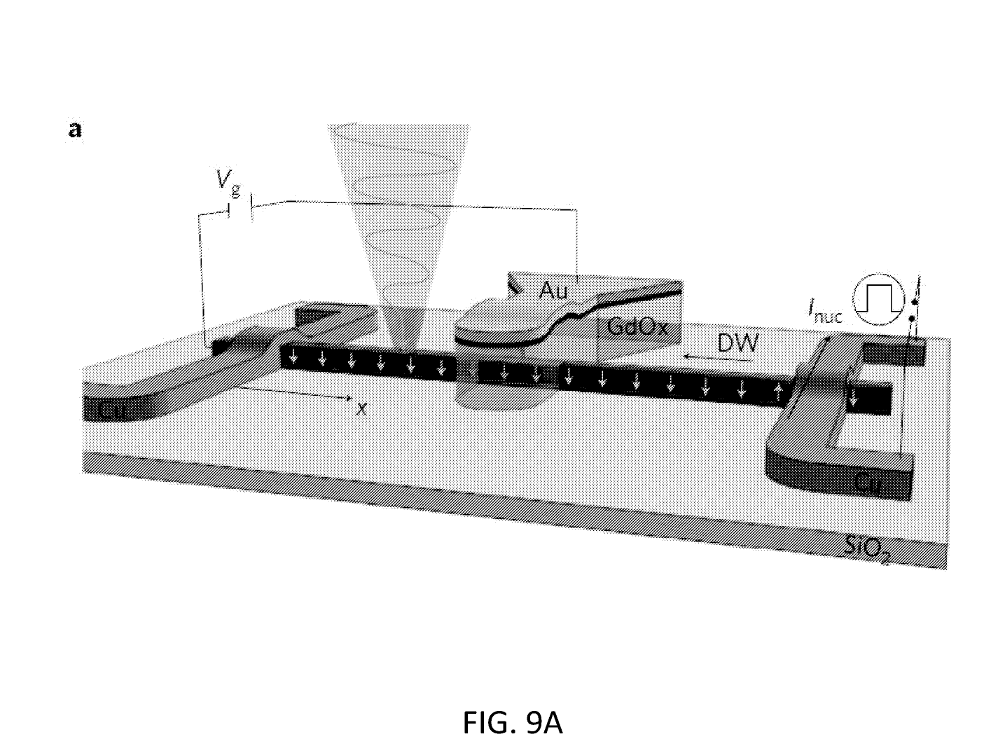

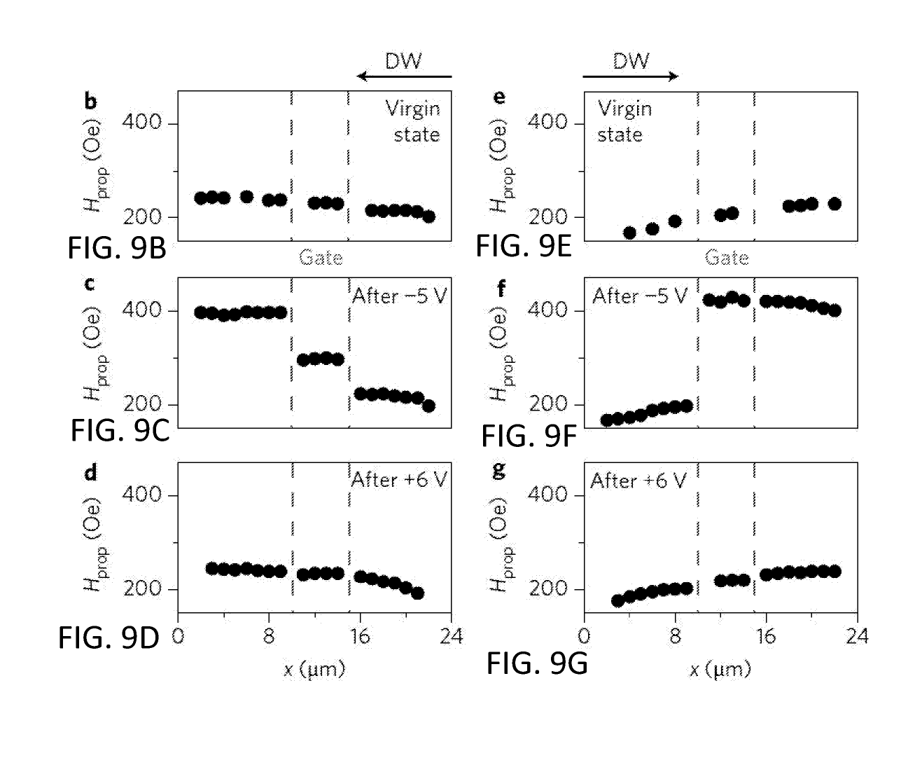

In an example device according to any of FIGS. 3C through 3F, where the ferromagnetic material layer is at least one nanostrip having a first end, a second end, and a central region, the lateral dimension l₂ of the gate oxide dielectric layer can be configured to be less than the length of the at least one nanostrip. The gate oxide dielectric layer can be disposed over a portion of the central region of the at least one nanostrip, such that an applied potential difference can cause a change in magnetic anisotropy of portions of the ferromagnetic material and generate a magnetic domain wall pinning site, at portions of the central region. Non-limiting examples implementations of a device including a ferromagnetic material layer having a longitudinal conformation are shown in FIGS. 9A, 10A, 11A and 14A, described in greater detail hereinbelow.

As non-limiting examples, the dielectric material can be based on at least one of: gadolinium, hafnium, terbium, zirconium, yttrium, tantalum, titanium, aluminum, silicon, germanium, gallium, indium, tin, antimony, tellurium, barium, bismuth, titanium, vanadium, chromium, manganese, cobalt, nickel, copper, zinc, niobium, molybdenum, palladium, cadmium, strontium, tantalum, niobium, cerium, praesydium, or tungsten, or any combination thereof. For example, the dielectric material can be an oxide, an oxynitride, a nitride, or a silicate of any of these materials. As other non-limiting examples, the dielectric material can be aluminum oxide (AlOₓ), bismuth zinc niobate, hafnium oxide (AlOₓ), barium strontium titanate, tantalum oxide, or gadolinium oxide (GdOₓ). In any example herein, the dielectric material can be Gd₂O₃ or SrTiO₃.

In any example herein, the dielectric material can be formed from any dielectric material or electrolyte having high ion mobility that is considered for application, e.g., in fuel cells or electrochemical metallization memory cells. For example, dielectric material layer can be formed from any of the high ionic mobility materials known in the art, and listed, e.g., in R. Waser et al., Advanced Materials, vol. 21, pp. 2632-2663 (2009), or W. Lu et al., Materials Research Society Bulletin, vol. 37, pp. 124-130 (2012), each of which is incorporated herein for the disclosure of the dielectric materials and/or electrolytes.

In any example herein, the dielectric material can be formed to have an amorphous structure, or a semi-crystalline structure, since such structures can facilitate higher mobility of ion vacancies.

In any example herein, the dielectric material can be formed from an organic material having high mobility ionic species, including any applicable polymeric material. As non-limiting examples, an example device that includes an organic dielectric can be used to provide an organic memory, an organic spintronic device, an organic magnetic recording device, an organic memristor, an organic non-volatile memory device, an organic magnetoresistive random-access memory device, an organic voltage-controlled magnetic memory, an organic voltage-tunable magnetic sensor, an organic voltage-controlled lateral conductive device, an organic electrically controllable catalysis device, an organic voltage controlled optical switch, an organic responsive window tinting device, or an organic display device.

In any example herein, the ionic species of the dielectric material layer, including the gate oxide dielectric and the intermediate oxide layer, can be an anion of oxygen, such as, but not limited to, an oxide, an oxynitride, or a silicate. For example, the dielectric material layer can be formed as an oxide, an oxynitride, or a silicate a transition metal or of a rare earth metal.

In any example herein, the gate oxide dielectric layer can include at least one of gadolinium, hafnium, terbium, zirconium, yttrium, tantalum, titanium, and aluminum.

In various example devices and configurations according to the principles herein, including the example devices of any of FIGS. 3A through 3F or the device configurations of any of FIGS. 4A through 4C, the ferromagnetic material layer of the active region of the device is formed from any electrically conductive material that is ferromagnetic and is configured to reversibly uptake an amount of at least one ionic species. The electrically conductive material layer can include aluminum, a transition metal, a rare earth metal, and/or an alloy of any of these conductive materials. As non-limiting examples, the ferromagnetic material layer can include iron, nickel, cobalt, samarium, dysprosium, yttrium, chromium, or an alloy of at least one of iron, nickel, cobalt, and samarium. In various examples, the alloy can be an alloy of one or more transition metals, or an alloy of one or more rare earth metals, or an alloy that includes at least one transition metal and at least one rare earth metal. The alloy can be a binary or ternary system of any of these conductive materials.

In an example where the ferromagnetic material is in electrical communication with an electrically conductive material layer, the electrically conductive material layer can include electrically conductive material layer can include aluminum, a transition metal, a rare earth metal, and/or an alloy of any of these conductive material. For example, the electrically conductive material layer can include gold, copper, tantalum, tin, tungsten, titanium, tungsten, cobalt, chromium, silver, nickel, iron, nickel, cobalt, samarium, dysprosium, yttrium, chromium.

In various example devices and configurations according to the principles herein, including the example devices of any of FIGS. 3A through 3F or the device configurations of any of FIGS. 4A through 4C, the electrically conductive material layer can be formed as a nanostrip disposed in the x-y plane. In another example, the electrically conductive material layer from one or more nanostrip.

In various example devices and configurations according to the principles herein, including the example devices of any of FIGS. 3A through 3F or the device configurations of any of FIGS. 4A through 4C, the example electrically conductive contact herein can be formed from gold, platinum copper, tantalum, tin, tungsten, titanium, tungsten, cobalt, chromium, silver, nickel, ruthenium or aluminum, or a binary or ternary system of any of these conductive materials.

The ferromagnetic material layer of the example devices and configurations according to the principles herein are configured for reversible uptake of an amount of the at least one ionic species. That is, the ferromagnetic material layer is configured to be oxidizable, or reducible, or otherwise capable of reversibly coupling with the at least one ionic species. The dielectric material layer serves as a reservoir of the ionic species. The amount of the higher-mobility ionic species in the dielectric material layer can be changed (increased or decreased) by regulating the temperature and/or electromagnetic radiation exposure of the dielectric material. The direction of the applied potential difference across the interface between the electrically conductive material layer and the dielectric material layer causes the mobile ionic species to migrate into (or out of) the portions of the electrically conductive material layer proximate to the interface. The magnitude of the potential difference drives the ionic species into the electrically conductive material layer at interface, such that the state of electrically conductive material layer changes proximate to the interface to change the properties of the electrically conductive material. For example, the mobile ionic species can be driven to a depth of up to about 0.1 nm, about 0.3 nm, about 0.5 nm, about 0.8 nm, about 1 nm, about 1.2 nm, or more, into the electrically conductive material layer (as measured from the interface). This change in the state of electrically conductive material layer results in a change in the functional property of the example device.

The example devices and configurations according to the principles herein are capable of retaining the change of the functional property even after discontinuance of the application of the potential difference. That is, the changed state of the ferromagnetic material layer (from the presence of the at least one ionic species) is a metastable state that persists for a period of time even after discontinuance of the applied potential difference. This metastable state can persist for a (persistence) period of time up to about 10 nanoseconds, about 100 nanoseconds, about 500 nanoseconds, about 1 microsecond, about 500 microseconds, about 1 millisecond, about 100 milliseconds, about 500 milliseconds, about 1 second, about 5 seconds, about 10 seconds, about 30 seconds, about 60 seconds, about 3 minutes, about 5 minutes, about 10 minutes, about 30 minutes, about 60 minutes, or longer (including substantially longer periods of time). Once the ionic species are driven into the ferromagnetic material layer under an applied potential difference in a first direction, this changed state of the ferromagnetic material layer (a first state) persists in the metastable state (for the duration of its persistence period) unless a potential difference having opposite polarity (i.e., in an opposite direction) is applied. A first, non-zero amount of the ionic species is present in the ferromagnetic material layer (e.g., as quantified by proportion or concentration) in this first metastable state. When a potential difference of an opposite polarity is applied, the at least one ionic species migrate out of the electrically conductive material layer, back to the dielectric material layer. This results in a smaller amount of the ionic species remaining in the ferromagnetic material layer (as quantified by proportion or concentration), to provide a second metastable state. The overall example device has different functional properties depending on whether the ferromagnetic material layer is in the first metastable state or in the second metastable state.

Example systems, methods, and apparatus are provided for selectively and locally “programming” different functional properties into different spatial regions of an example device, configured in any applicable configuration. For example, the reversible metastable change in state of the electrically conductive material layer can be “programmed” at different local spatial regions of an example device. Through discrete local application of the potential difference, differing regions of the example device can be caused to exhibit different magnetic anisotropies. Accordingly, example systems, methods, and apparatus are provided for locally and controllably modifying the state of ferromagnetic material layer, thereby reversibly, locally and controllably changing the functional properties of the example device. This example provides for direct “writing” of the functional properties at different portions of the example devices.

In various example implementations, the voltage applying element can be configured to apply a sufficiently high potential difference of a magnitude of about 100 millivolts, about 0.1 V, about 0.5 V, about 1V, about 1.5, about 2 V, about 3V, about 5 V, about 7 V, about 10V, about 20 V, about 50 V, about 100 V, or greater. As described herein, the polarity of the potential difference depends on the type of metastable state sought, the existing state of the device at the time the potential difference is applied, and the device layer structure.

The direction of ionic motion is determined by the charge of the ionic species and the polarity of the applied voltage. Properties of the electrically conductive material layer depend on the chemical composition and defect structure at the interface formed with the dielectric material layer, accumulation or depletion of the mobile ionic species at this interface can significantly modify the properties of the target material layer. Also, motion of the mobile ionic species into a portion of the target layer, beyond the immediate interface region, facilitates the modification of the chemical composition and defect structure of parts of the target material layer. This allows access to additional material properties that might not be directly sensitive to the interface.

In various example implementations, the temperature at regions of the example device can be regulated using a heating element, a thermoelectric element, or a laser beam. The heating element may be configured as a resistive element coupled to the spatial region of the device. The thermoelectric element can be thin-film thermoelectric, such as but not limited to a Bi₂Te₃-based film or a CoSb₃-based skutterudite material.

In an example implementation, to increase the proportion of mobile inic species in the dielectric oxide layer, spatial regions of the device can be heated to a threshold temperature value of about 30° C., about 50° C., about 70° C., about 100° C., about 120° C., about 150° C., about 170° C., about 200° C., about 250° C., about 300° C., about 350° C. or higher. In an example, the threshold temperature value is set to be within the range of allowable operating temperatures of an example device.

In any example herein, the example device could be configured as a flexible device or a substantially rigid device. In an example device, the target layer and/or the dielectric material layer could be formed of a flexible material. In an example, the example flexible device could include a flexible substrate, and the target layer and dielectric material layer could be disposed over at least a portion of the flexible substrate. In another example, the example device could be configured with a combination of flexible regions and more rigid regions. In any example herein, one or both of the ferromagnetic material layer and dielectric material layer could be grown, using any deposition technique and tool in the art, on a large area substrate that includes flexible and rigid regions.

Non-limiting examples of flexible substrates include thin wood or paper, vinyl, leather, or other fabric (including artwork or other works on canvas), a polymer or polymeric material. Non-limiting examples of applicable polymers or polymeric materials include, but are not limited to, a polyimide, a polyethylene terephthalate (PET), a silicone, or a polyeurethane. Other non-limiting examples of applicable polymers or polymeric materials include plastics, elastomers, thermoplastic elastomers, elastoplastics, thermostats, thermoplastics, acrylates, acetal polymers, biodegradable polymers, cellulosic polymers, fluoropolymers, nylons, polyacrylonitrile polymers, polyamide-imide polymers, polyarylates, polybenzimidazole, polybutylene, polycarbonate, polyesters, polyetherimide, polyethylene, polyethylene copolymers and modified polyethylenes, polyketones, poly(methyl methacrylate, polymethylpentene, polyphenylene oxides and polyphenylene sulfides, polyphthalamide, polypropylene, polyurethanes, styrenic resins, sulphone based resins, vinyl-based resins, or any combinations of these materials.

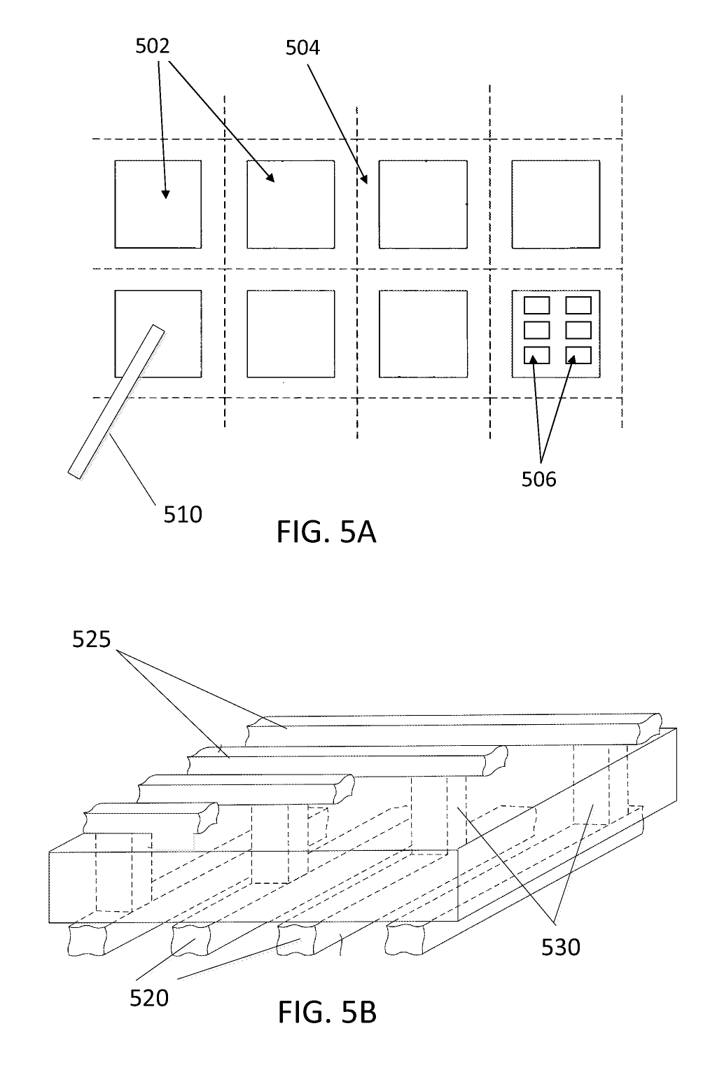

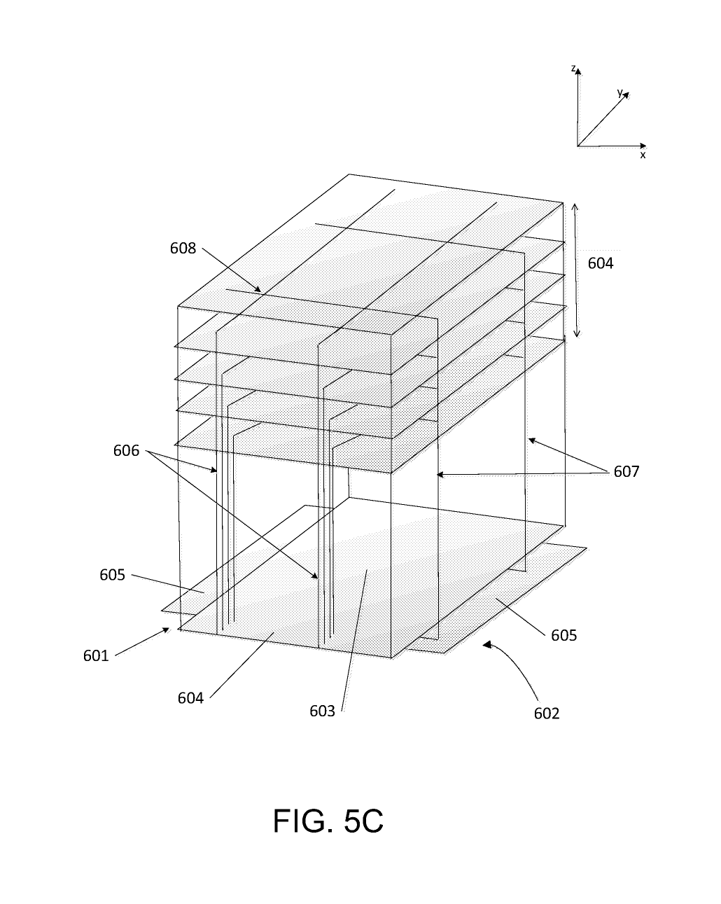

An example array of device elements according to the principles herein can be a configured as a two-dimensional array (illustrated in FIGS. 5A and 5B) or a three-dimensional, multi-layer array (illustrated in FIG. 5C). Device elements of the 2-D or 3-D array can be separately addressable. The device elements can be configured as any of the example devices or configurations herein, including the example devices of any of FIGS. 3A through 3F, or the device configurations of any of FIGS. 4A through 4C. The example systems and apparatus of FIGS. 5A, 5B, and 5C, include components and circuits for “writing” (e.g., setting a device component to a first metastable state or a second metastable state) or “reading” from device elements of the example arrays. The read operations may vary depending on the type of application, and can involve, e.g., detecting magnetic anisotropy of a portion of a device element, sensing the charge of a particular device element, or passing current through the device element.

FIG. 5A shows an example 2-D array of device elements according to the principles herein. The example 2-D array includes a plurality of device elements 2402 disposed in separately addressable regions. The example 2-D array can include at least one interstitial region 504 that is devoid of device elements 502. As shown in FIG. 5A, the 2-D array can also include one or more components 506, such as but not limited to at least one processing unit, a power source, power circuitry, one or more sensors (such as but not limited to at least one temperature sensor and/or at least one electromagnetic radiation sensor), at least one wireless communication component, or other integrated circuit (CMOS) components. In some examples, the power source can be a wireless power source. FIG. 5A also illustrates a regulating element 510 that can be coupled to the spatial region of a device element. The regulating element 510 can be configured according to any example herein.

FIG. 5B illustrates an example 2-D array of device elements, configured in a cross-bar geometry. The example 2-D crossbar array composed of a lower layer of approximately parallel cross-bar wires 520 that are overlain by an upper layer of approximately parallel cross-bar wires 525. The parallel cross-bar wires of the upper layer 525 can be oriented roughly perpendicular, in orientation, to the parallel cross-bar wires of the lower layer 520. In another example, although the orientation angle between the upper and lower parallel cross-bar wires may vary. The two layers of cross-bar wires form a lattice, or crossbar, in which each cross-bar wires of the upper layer 525 overlies all of the cross-bar wires of the lower layer 520. The device elements 530 are disposed between an upper layer cross-bar wire 525 and a lower layer cross-bar wire 520, formed between the crossing nanowires at the overlap intersection of the two layers of cross-bar wires. Consequently, each cross-bar wire 525 in the upper layer is connected to every cross-bar wire 520 in the lower layer through a device element and vice versa. Each device element 530 is separately addressable through the selection of the respective upper layer cross-bar wire 525 and lower layer cross-bar wire 520. That is, lower cross-bar wires 520 and upper cross-bar wires 525, can be used to uniquely address, including applying voltages to read data and/or to write data (i.e., set to a first metastable state or a second metastable state) to the device elements. Portions of the cross-bar wires 520, 525 between the device elements can also be configured to serve as conductive lines to the device elements, and as portions of the regulating elements.

FIG. 5C shows an example 3-D, multi-layer array of device elements according to the principles herein. The 3-D multi-layer array is configured as a base 602, a multi-layer arrangement of 2-D arrays 604 disposed over the base, and conductive lines 606, 607 leading from the base to provide electrical communication with each layer of the multilayer structure. At least one device element and regulating element are positioned at the intersections 608 in each 2D array on each layer. Conductive lines 606 can be driven independently using the external applied voltage in each layer. The base 602 includes a wiring area 603 (including CMOS circuitry), and contact areas 604 and 605 for the conductive lines. The multi-layer arrangement of 2-D arrays 602 can include any number of layers (i.e., greater or fewer than four layers). The base 602 includes circuitry and other components for providing instructions for writing (e.g., setting a device component to a first metastable state or a second metastable state) or reading from the 2-D arrays 604 with outside sources. The read operations may vary depending on the types of device, and can involve, e.g., sensing the charge of a particular device element, passing current through the device element, detect magnetic anisotropy. For example, an external voltage can be applied to respective device element(s) using conductive lines 606 and 607. In some examples, wiring area 603 can include a column control circuit including a column switch and/or a row control circuit including a row decoder. The base can be integrated with (CMOS) circuitry for selectively address device elements, providing input/output functions, buffering, logic, or other functionality. For example, the CMOS circuitry can be configured to selectively address, including applying the potential to, the targeted device element(s). The CMOS circuitry can be used to effect the applying the read and write voltages to the conductive lines as described herein.

In the example of FIG. 5C, conductive lines 607 are illustrated as being coupled in common in the layers. In other examples, conductive lines 607 may be driven independently in two or more layer using the external applied voltage. The CMOS circuitry can be configured to selectively address (including applying external voltages to) ones of the device elements (the targeted device elements) using the conductive lines 606, 607.

In any example according to the principles herein, including the example devices, configurations, or arrays of any of FIGS. 3A through 5C, the ferromagnetic material layer of the example device can be disposed over at least one of: an electrically conductive layer, at least one additional ferromagnetic material layer, at least one additional oxide dielectric layer, a tunnel barrier layer, and an integrated circuit.

In any example according to the principles herein, including the example devices, configurations, or arrays of any of FIGS. 3A through 5C, the ferromagnetic material layer can be disposed over an electrically conductive material layer and/or a magnetic tunnel junction.

In any example system, method, apparatus or device according to the principles herein, at least one of a conductive contact or a gate electrode can be formed as a mask. For example, a shadowed mask can be used as electrodes for providing electrical contact to the example device.

Example methods are also provided for programming data to an example device. The example device includes a ferromagnetic material layer disposed in an x-y plane, a gate oxide dielectric layer disposed over the ferromagnetic material layer, and a gate electrode layer disposed over, and in electrical communication with, the gate oxide dielectric material layer. The example device is configured such that the lateral dimension of the ferromagnetic material layer is greater than the lateral dimensions of both the gate oxide dielectric layer and the gate electrode layer. The example method includes nucleating a magnetic domain wall at a region of a ferromagnetic material layer of a device, applying a first magnetic field having a first polarity to the device, and applying a potential difference between the gate electrode layer and the ferromagnetic material layer. The gate electrode layer, the gate oxide dielectric layer, and the ferromagnetic material layer of the example device are configured such that a potential difference applied in a first direction between the gate electrode layer and the ferromagnetic material layer generates a domain wall pinning site at a region of the ferromagnetic material layer, and a potential difference applied in a second direction, opposite to the first direction, between the gate electrode layer and the ferromagnetic material layer substantially eliminates the domain wall pinning site.

In various examples, the magnitude of the potential difference can be about 0.1 V, about 0.5 V, about 1V, about 1.5, about 2 V, about 3V, about 5 V, about 7 V, about 10V, about 20 V, about 50 V, about 100 V, or greater.

In an example, to nucleate the magnetic domain wall, a mechanical stress can be applied to the region of the ferromagnetic material layer that is not in the overlap region.

To program the example device, each successive magnetic field pulse is configured to be of lower amplitude than the previous pulse. The example method can further include applying to the device a second magnetic field having a smaller amplitude than the first magnetic field pulse.

The second magnetic field pulse can have a second polarity that is opposite to the first polarity of the first magnetic field.

The polarity of the magnetic field applied to a region of the device determines the type of information programmed to the region of the device. For example, a magnetic field with a first polarity can be used to program a first type of information to the device, while a magnetic field with a second polarity programs a second type of information to the device that is different from the first type of information.

The first type of information can be a first magnetization direction of a portion of the device, while the second type of information can be a second magnetization direction that is different from the first magnetization direction.

As a non-limiting example, a n-bit non-volatile memory cell can be derived based on an example device including n−1 gate electrodes coupled to the gate oxide dielectric material at differing portions of the example device. Any example device or device configuration according to the principles described herein, including the example devices, configurations, or arrays of any of FIGS. 3A through 5C, can be configured with n−1 gate electrodes to function as a non-volatile memory cell. For example, the n−1 gate electrodes can be disposed linearly relative to each other along the example device. The example device can be programmed as a cascaded sequence of domain wall traps, with successively increasing pinning strength. A bit sequence can be written using a sequence of n magnetic field pulses applied to the example device, with each subsequent pulse having successively decreasing amplitude. To write a bit pattern, a new domain wall can be initialized using a domain wall injection element before each global magnetic field pulse. According to the principles herein, the domain wall can be nucleated at a point in the example device using mechanical stress, an optical means, an electrical means, or any other applicable means. The magnetic field pulse amplitudes can be configured such that the mth pulse drives the initialized domain wall past the first m−1 domain wall traps, but not past the mth trap.

A complementary field pulse sequence can be used to read out the bits. As non-limiting examples, readout can be performed using an optical means (such as but not limited to a laser) and/or an electrical means (such as but not limited to a magnetic tunnel junction coupled to the example device) placed on or coupled to a bit. For the readout process, a first bit (bit 1) can be read and then set to a reference state. Subsequent bits can be read out in sequence by applying read and reset field pulses of equal amplitude, but opposite polarity for each bit. To read the mth bit, the magnetic field pulse amplitude can be set to be between the pinning strengths of the (m−1)th and mth domain wall traps. If the state of the mth bit is different from the reference state, the read pulse sweeps the domain wall from the (m−1)th domain wall trap through the first bit, where it is detected. A reset pulse, accompanied by a domain wall nucleation pulse, can be used to reset all previously read bits to a reference state.

An example system including an array of such example devices could be driven by a single global field source, with any particular device register addressed as described. Some or all of the other registers can be placed in an inactive state by setting domain wall traps to a high pinning state.

Efficient ionic motion typically occurs at high temperatures of several hundred degrees Celsius. A novel innovation of the example systems, methods and apparatus herein is to provide example devices with enhance ionic mobility. Through the novel device configurations according to the principles described herein, the enhanced ionic mobility is readily achievable at low temperatures and even at room temperature. Fast motion of oxygen ions is derived at room temperature, and under moderate voltages, by employing the novel device configurations and design concept herein.

An example device with enhanced ionic mobility can be configured such that the oxide dielectric layer is divided into two layers, instead of a single continuous oxide layer. The double-layer oxide dielectric layer includes a gate oxide dielectric layer and an intermediate oxide dielectric layer. As a non-limiting example, the double layer includes a thinner oxide dielectric layer as the intermediate oxide dielectric layer and a thicker oxide dielectric layer as the gate oxide dielectric layer. FIGS. 3B, 3E and 3F show non-limiting examples of such a device structure. In any of these example device structures, the thinner intermediate oxide dielectric layer can be, e.g., an ultrathin gadolinium oxide (GdOx) layer, on the order of a few nm thick forming an interface with the ferromagnetic material layer (formed from, e.g., Co, Fe, Ni, Sm, or any combination of these metals). The thinner, intermediate oxide dielectric layer helps to protect the ferromagnetic material layer from oxidation from ambient air. The second, thicker gate oxide dielectric layer which extends underneath the gate electrode area and therefore provides an open oxide edge underneath the gate electrode edge. The second, thicker gate oxide dielectric layer can be formed from the same dielectric as the thinner material (e.g., GdOx layer) or from a different material than the first, thinner oxide dielectric (thereby creating an oxide mismatch). The second, thicker gate oxide dielectric layer can be thicker than the first, thinner intermediate oxide dielectric layer by a factor of about 2, about 3, or higher. The second, thicker gate oxide dielectric layer can be configured to have any thickness that reduces leakage current in the device.

The lateral dimension of the second, thicker dielectric can be approximately the same as, somewhat smaller than, or somewhat larger than, the lateral dimension of the gate oxide dielectric layer. The relative lateral dimensions of the gate electrode layer and the oxide dielectric can be configured to obtain sufficiently high oxygen mobility near the edge of the second, thicker oxide dielectric, to derive the domain wall pinning sites. The gate electrode edge also acts as the triple phase boundary which is where ionic, electronic and gas phases meet and where oxygen exchange occurs most effectively. Therefore, by providing this open oxide underneath the gate electrode edge (i.e., triple phase boundary), a fast diffusion path is provided for oxygen ions, because diffusion can occur at the surface or edge rather than through the bulk.

In any example herein, the example device can configured such that the domain wall pinning site is non-volatile, and persists after the applied voltage is discontinued for a period of time. For example, the device can configured such that, after the applied potential difference is discontinued, the domain wall pinning site persists for about 10 nanoseconds, about 100 nanoseconds, about 500 nanoseconds, for several milliseconds, for several seconds, for several minutes, for several hours, for several days, or longer.

This novel device designs according to the principles herein, including the example devices, device configurations, and arrays of any of FIGS. 3A-5C, allows voltage-induced changes to the oxygen stoichiometry of the ferromagnetic material/dielectric oxide material interface at room temperature, and results in a strong modification of magnetic anisotropy. In some of the example device, ionic motion can occur efficiently along the open oxide edge, such that the changes in magnetic anisotropy occur at the immediate ferromagnetic material film area underneath the oxide edge. Moreover, at a given applied gate voltage, oxygen ions accumulate over time, so the local degree of anisotropy modification can be controlled by the applied bias dwell time.

The spatial confinement of ionic motion can result in the creation of very sharp and deep wells in the magnetic anisotropy energy landscape, which then act as domain wall pinning sites that trap passing domain walls. Therefore, this example device designs and configurations herein facilitate the creation of voltage-programmable domain wall pinning sites that can be set to any desired pinning strength and that can be used to stop the propagation of magnetic domain walls at precise locations.

The example systems, methods, and apparatus according to the principles herein are not limited to voltage-induced magnetic anisotropy modifications at the electrode edge. At elevated temperature, the example device can be safely operated without any permanent modifications of magnetic anisotropy due to the temperature increase itself. This operating temperature, which can be similar to the operating temperature of most semiconductor electronic devices, can be set to be large enough to allow efficient voltage driven motion of oxygen ions in the bulk of the dielectric oxide material layer. A gate voltage applied to the device at this elevated temperature then facilitates inducing of oxygen ion motion and therefore magnetic anisotropy modifications in the entire electrode area.

Example methods are also provided for tuning the functional properties of an example device. An example method includes (i) irradiating a portion of the example device using electromagnetic radiation, and/or (ii) change the temperature of the portion of the device. The example method includes applying a potential difference in a direction across the dielectric material layer and the electrically conductive material layer for a duration of time sufficient to cause a change in the proportionate amount of the at least one ionic species in a portion of the ferromagnetic material layer proximate to the interface. As described herein, this causes a change of a local magnetic property of the example device. As described herein, the example device retains the type of property change after discontinuance of the irradiating, and/or the temperature change, of the device.

In various examples, the duration of time for applying the potential difference can be about 1.0 nanosecond, about 10 nanoseconds, about 20 nanoseconds, about 50 nanoseconds, about 100 nanoseconds, about 1 microsecond, about 500 microseconds, about 1 millisecond, about 100 milliseconds, about 500 milliseconds, about second, about 5 seconds, about 10 seconds, about 30 seconds, about 60 seconds, about 3 minutes, about 5 minutes, about 10 minutes, about 30 minutes, about 60 minutes, or longer (including substantially longer periods of time).

In dielectric oxides formed as thin-film amorphous metal oxides, ionic exchange is particularly efficient and occurs readily at room temperature. Accordingly, the dielectric material layers (including the gate dielectric oxide layers and/or the intermediate layer) of any example device herein can be formed from an amorphous or semi-crystalline dielectric material. An amorphous or semi-crystalline dielectric material can provide a higher proportion of mobile ionic species. Accordingly, the example device can be operated at temperatures closer to room temperature or lower temperatures (e.g., temperatures on the order of about 150 C or less) with a sufficiently high proportion of mobile ionic species. Where the dielectric material layers (including the gate dielectric oxide layers and/or the intermediate layer) of any example device herein is formed from a more crystalline dielectric material, the dielectric material may provide a lower proportion of mobile ionic species. These example devices may be operated at higher temperatures (e.g., temperatures on the order of about 150 C, about 200 C or greater) to derive a sufficiently high proportion of mobile ionic species.

In various examples, changing the temperature can include heating the portion of the device to a temperature above a threshold temperature value. The threshold temperature value can be about 25° C., about 40° C., about 50° C., about 70° C., about 100° C., about 120° C., about 170° C., about 200° C., about 225° C., about 250° C., or higher.

In various examples, the magnitude of the potential difference can be about 1V or less, about 2 V, about 3V, about 5 V, about 7 V, about 10V, or greater.

An example device according to example systems, apparatus and methods herein can be introduced integrated into the structure of existing device structures, to provide additional capabilities for tuning the operation of the device structure. For example, an example device according to the principles herein can be integrated into a memory device such as a magnetic tunnel junction (MTJ), e.g., the MTJ structure shown in FIG. 1A. The electrical resistance of the MTJ is different depending on whether the ferromagnetic layers (M1 and M2) are magnetized in substantially the same direction, or in different directions. Changing the direction that one ferromagnetic layer of the MTJ stack is magnetized changes the resistance state of the MTJ. The relative magnetization direction of the two ferromagnetic layers (M1 and M2) serves as the memory state, and the MTJ resistance providing a readout mechanism for the memory state. As is known to those in the art, setting the memory state of a MTJ, i.e., changing the state or “writing” the state, is achieved by switching the magnetization direction of one of the layers (referred to as the “free layer”). This switching can be achieved by applying a magnetic field, or by using electrical current flowing through or nearby the device. The amount of energy required to write the state of the MTJ depends on the magnetic anisotropy of the free layer, so that a more efficient device can be achieved using a lower anisotropy ferromagnetic free layer. However, in order to maintain a stable magnetization orientation in the bit after writing, a large magnetic anisotropy is required.

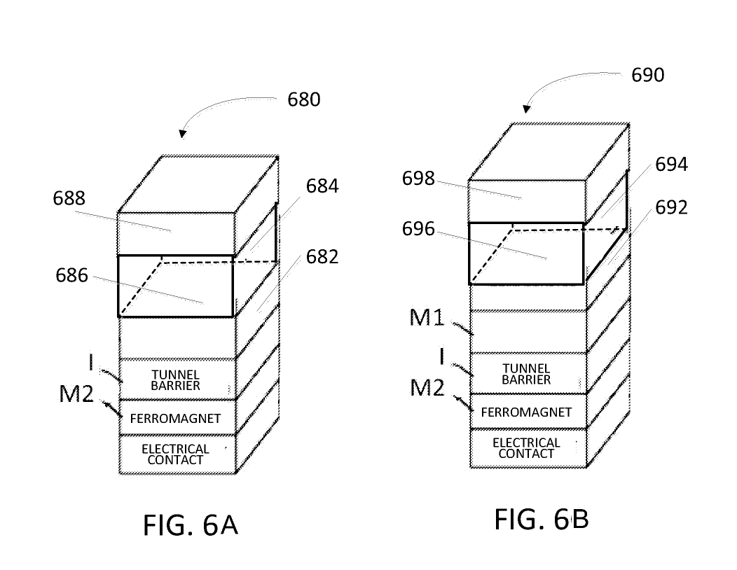

Example modified MTJ-devices according to example systems, apparatus and methods herein can be produced by integrating into the MTJ structure an example device according to the principles herein, to provide additional capabilities for tuning the magnetic anisotropy of the ferromagnetic free layer. FIGS. 6A and 6B show example modified MTJ-devices according to the principles herein. In the example of FIG. 6A, the modified MTJ-device 680 includes a target layer 682 of a ferromagnetic material forming an interface 686 with a dielectric material layer 684, and a gate electrode layer 688 in electrical communication with the dielectric material layer 684. In this example, the target layer 682 is part of the MTJ stack, and forms the MTJ structure with the tunnel barrier layer and the ferromagnetic layer M2. Regulation of the migration of the ionic species into the target layer can directly affect the functioning of the MTJ stack. In the example of FIG. 6B, the example modified MTJ-device 690 includes a target layer 692 of a ferromagnetic material forming an interface 696 with a dielectric material layer 694, and a gate electrode layer 698 in electrical communication with the dielectric material layer 694. The target layer 682 is coupled to the ferromagnetic layer M1 of the MTJ stack (formed from ferromagnetic layer M1, the tunnel barrier layer, and ferromagnetic layer M2). In this example, the target layer 682 functions as a spacer layer to the ferromagnetic layer M1 of the MTJ stack. Regulation of the migration of the ionic species into the target layer affects the functioning of the MTJ stack through the coupling of the target layer to the ferromagnetic layer M1. In the example modified MTJ-devices of both FIGS. 6A and 6B, the migration of the at least one ionic species from the dielectric material layer to the target layer can be used to tune the functioning of the MTJ stack. The modification of the proportionate amount of the at least one ionic species in portions of the target layer proximate to the interface causes a change in the magnetic anisotropy of the target layer. In these non-limiting examples, by reducing the magnetic anisotropy in the MTJ free layer, the writing process of the device becomes more efficient. By subsequently increasing the magnetic anisotropy in the MTJ free layer, the data retention characteristics of the example modified MTJ-devices are improved. An example device herein integrated into a modified-MTJ also facilitates programming of a memory device, by using the MTJ for readout-detection. Therefore, this example describes how the target layer of the example devices herein can be coupled to and integrated with other device structures, facilitating enhanced controls of the behavior or function of the device structure.

Following is a description of non-limiting example implementations of the systems, methods and apparatus described herein for regulation of magnetic anisotropy, and generating domain wall pinning sites, at portions of example devices that include an electrically conductive ferromagnetic material layer forming an interface with a dielectric material layer. While the examples below are directed to devices including cobalt as the ferromagnetic material layer and gadolinium oxide at the dielectric material layer, they are applicable to other example devices and device configurations according to the principles described herein.

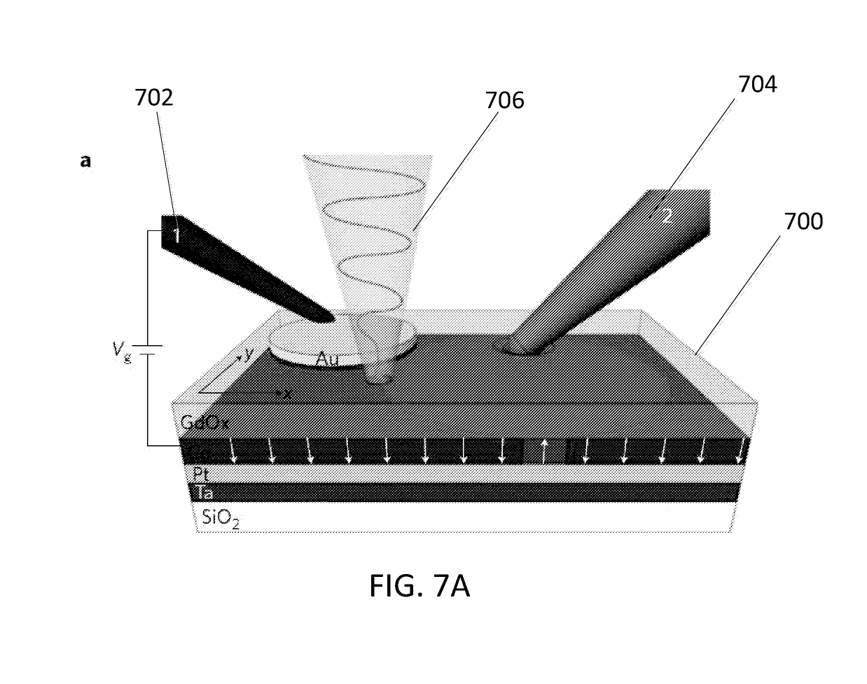

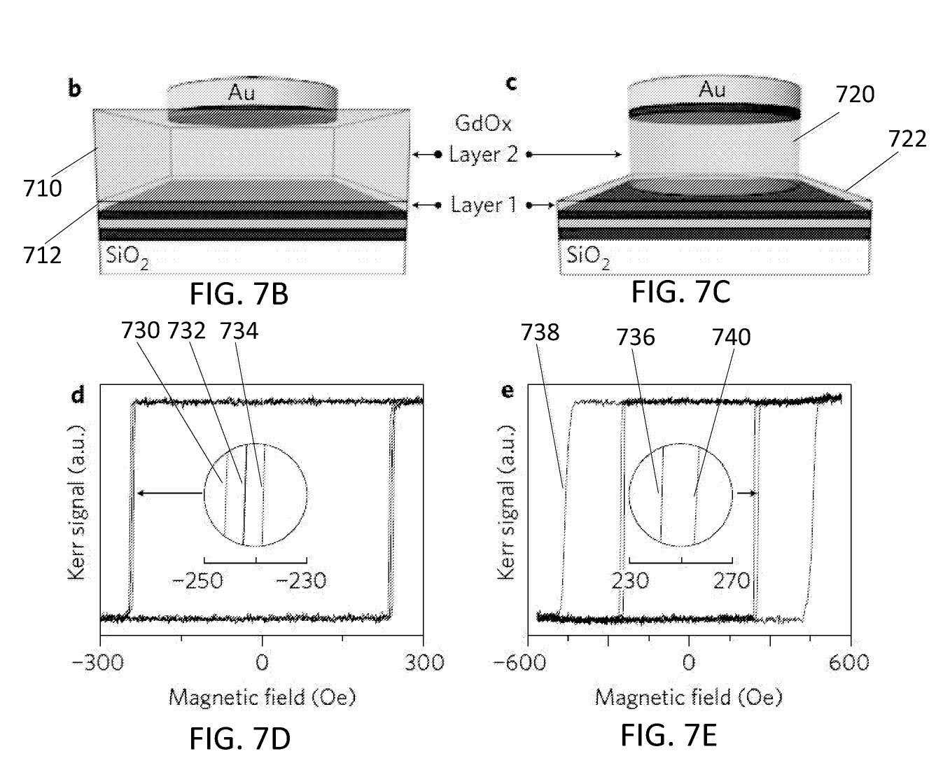

FIGS. 7A-7E show a schematic of an example measurement apparatus for measuring an example device and magnetic hysteresis loops from measurements of the example device. The example device of FIG. 7A has a Ta/Pt/Co/GdOx structure, which includes a bilayer of a ferromagnetic material (Co) forming an interface with a dielectric oxide (GdOx), and an electrical contact (Ta/Pt). A gate electrode formed from gold is shown disposed at a portion of the dielectric oxide.

FIG. 7A shows the schematic of the example measurement apparatus for measuring the example device 700. The measurement apparatus includes a BeCu microprobe 702 for voltage application, a tungsten microprobe 704 to create an artificial domain wall nucleation site, and a focused MOKE laser probe 706 to map out the magnetic domain expansion (in an x, y plane). The example device of FIG. 7A is fabricated as a structure with Ta(4 nm)/Pt(3 nm)/Co(0.9 nm)/GdOx(3 nm) films with strong PMA and an in plane saturation field of >10 kOe (GdOx, gadolinium oxide). On those films, a second 30-nm thick GdOx overlayer and a Ta/Au metal gate are deposited and patterned into two different geometries.

FIGS. 7B and 7C show the schematics of two different example devices having a bilayer dielectric oxide. FIG. 7B shows an example device in which the gate oxide dielectric layer 710 (layer 2) has a similar lateral dimension to the intermediate oxide layer 712 (layer 1). In example device of FIG. 7B, the GdOx overlayer is continuous and the Ta/Au layer is patterned into an array of 100-μm-diameter electrodes. FIG. 7C shows an example device in which the gate oxide dielectric layer 720 (layer 2) has a smaller lateral dimension than the intermediate oxide layer 722 (layer 1). In the example of FIG. 7C, the GdOx gate oxide dielectric layer is shown as substantially cylindrical in shape. In other examples, the gate oxide dielectric layer can be patterned to any cross-sectional shape. In example device of FIG. 7C, the GdOx and Ta/Au layer are patterned together into an array. The gate structure is nominally identical for the example devices of FIGS. 7B and 7C, but the example device of FIG. 7C exhibit an open oxide edge around the electrode perimeter, which is not present in example device of FIG. 7B.

The example devices of FIGS. 7A-7C are fabricated from films prepared by d.c. magnetron sputtering at room temperature under 3 mtorr argon with a background pressure of ˜1×10⁻⁷ torr, on thermally oxidized Si(100) substrates. The GdOx layers are deposited by reactive sputtering from a metal Gd target at an oxygen partial pressure of ˜5×10⁻⁵ torr. Under these deposition conditions the GdOx layer is amorphous. The layer thicknesses are determined from the deposition rate of each material, which is calibrated by X-ray reflectivity. The magnetic properties of the Ta(4 nm)/Pt(3 nm)/Co(0.9 nm)/GdOx(3 nm) films are characterized by vibrating sample magnetometry. The films exhibited an in-plane saturation field of >10 kOe, indicating strong perpendicular magnetic anisotropy, and a saturation magnetization of ˜1,200 e.m.u./(cm³ of Co). These measurement results indicate minimal Co oxidation during growth of the GdOx overlayer.

The gate electrodes are patterned on the continuous film using electron-beam lithography and liftoff. The metal electrodes in the example devices of FIGS. 7B and 7C include a Ta(2 nm)/Au(12 nm) sputter-deposited stack. Domain walls are nucleated in these devices by the Oersted field from a 25-ns-long current pulse (˜100 mA) injected through the Cu line.

Polar MOKE measurements are made using a 532 nm diode laser attenuated to 1 mW, focused to a ˜3-μm-diameter probe spot and positioned by a high-resolution (50 nm) scanning stage. The Ta/Au gate electrodes are thick enough to permit robust electrical contact, but thin enough that polar MOKE measurements could be made directly through the electrodes at the 532 nm wavelength.

Magnetic hysteresis loops are measured and the domain wall propagation field is determined at a fixed sweep rate of the magnetic field of 28 kOe s⁻¹. The electromagnet used to perform the measurements have a rise time of ˜300 μs, and a maximum amplitude of 650 Oe, indicating the maximum domain wall trapping potential that can be measured.

FIGS. 7D and 7E show hysteresis loops for the example devices of FIGS. 7B and 7C respectively. FIG. 7D shows the results of measurements taken using V_{g}=0 V (732), V_{g}=−7 V (734) and V_{g}=+6 V (730). FIG. 7D shows the results of measurements taken in the virgin state (736) and after V_{g}=−6 V for 180 s (738) and V_{g}=+6V for 300 s (740). The inset of each of FIGS. 7D and 7E show magnified sections of the hysteresis loops.

The influence of a gate voltage on domain wall propagation is investigated using the technique described schematically in FIG. 7A. The stiff tungsten microprobe is used to create an artificial domain nucleation site in the vicinity of a gate electrode by application of a local mechanical stress. A second, mechanically compliant BeCu probe is used to gently contact the electrode and apply a gate voltage V_{g}. Under the application of a magnetic field, a reversed domain nucleates underneath the tungsten tip and expands radially across the film. Magnetization reversal is locally probed using a scanning magneto-optical Kerr effect (MOKE) polarimeter. FIG. 7D shows hysteresis loops for the example device of FIG. 7B measured near the center of a gate electrode located ˜100 μm from an artificial nucleation site, with V_{g}=0 V, +6 V and −7 V. The coercivity H_{c} varies linearly and reversibly with V_{g} at a slope of ˜0.5 Oe V⁻¹, consistent with the influence of electron accumulation/depletion on domain wall creep.

The behavior of the example device of FIG. 7C is different. Under negative gate voltage, H_{c} increases with time at a rate that increases with increasing |V_{g}|. In contrast to sample A, when V_{g} is removed the higher H_{c}, state is retained. As seen in FIG. 7E, H_{c} increases by ˜230 Oe after applying V_{g}=−6 V for 180 s. This change is two orders of magnitude larger and of opposite sign compared to the example device of FIG. 7B at the same V_{g}. Subsequent application of positive V_{g}=+6 V for 300 s returns H_{c}, to within 10 Oe of its initial state. H_{c}, can be cycled in this way many times and remains stable at V_{g}=0 for at least several days.

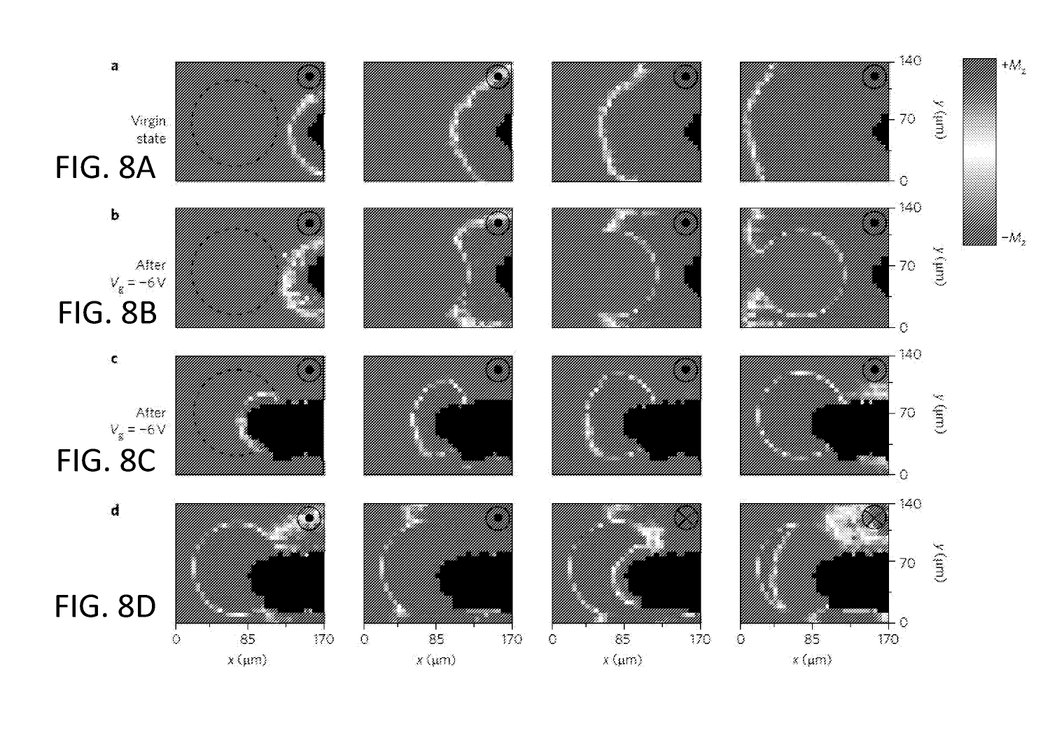

FIGS. 8A-8D shows examples of measured space- and time-resolved domain expansion. FIGS. 8A-8D shows the sequences of polar MOKE maps, showing domain expansion on sample B with increasing time (left to right) under a driving field of H=170 Oe. The sequence of FIG. 8A shows the virgin device state and the sequences of FIGS. 8B-8D correspond to the high-H_{c} state with H_{c}=460 Oe after application of V_{g}=−6 V for 180 s. All maps (FIGS. 8A-8D) are measured at V_{g}=0 V with an artificial nucleation site either outside (FIGS. 8A-8B) or inside (FIGS. 8C-8D) the region of the gate electrode layer. Domain expansion in FIG. 8D is a continuation of FIG. 8C with the H direction reversed after the second map. The sequences of FIGS. 8A-8C span 9.8 ms, 9.8 ms and 4.2 ms, respectively. The sequence of FIG. 8D spans 12.2 ms and H is reversed after 6.2 ms. Symbols in the upper right corner of each map (FIGS. 8A-8B) indicate H direction. Dashed black circles in FIGS. 8A-8C show the outline of the gate electrode, and the black map area (FIGS. 8A-8B) corresponds to the tungsten microprobe used to create the artificial nucleation site.

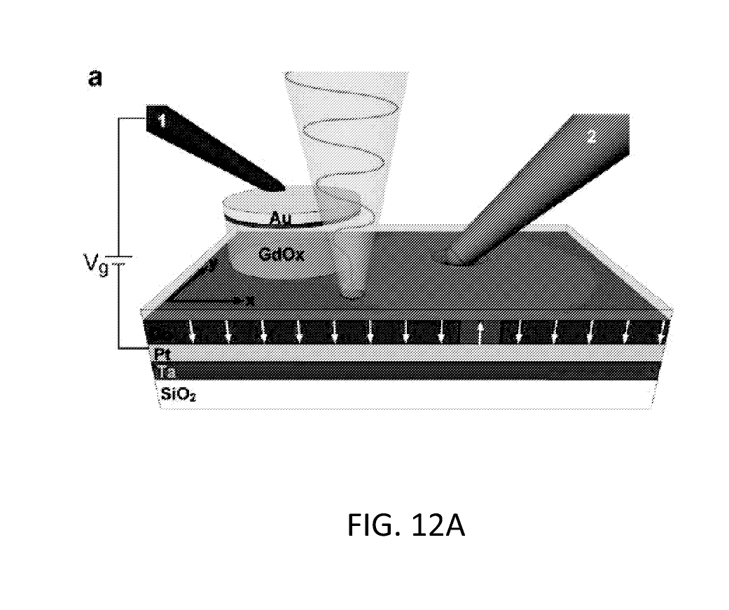

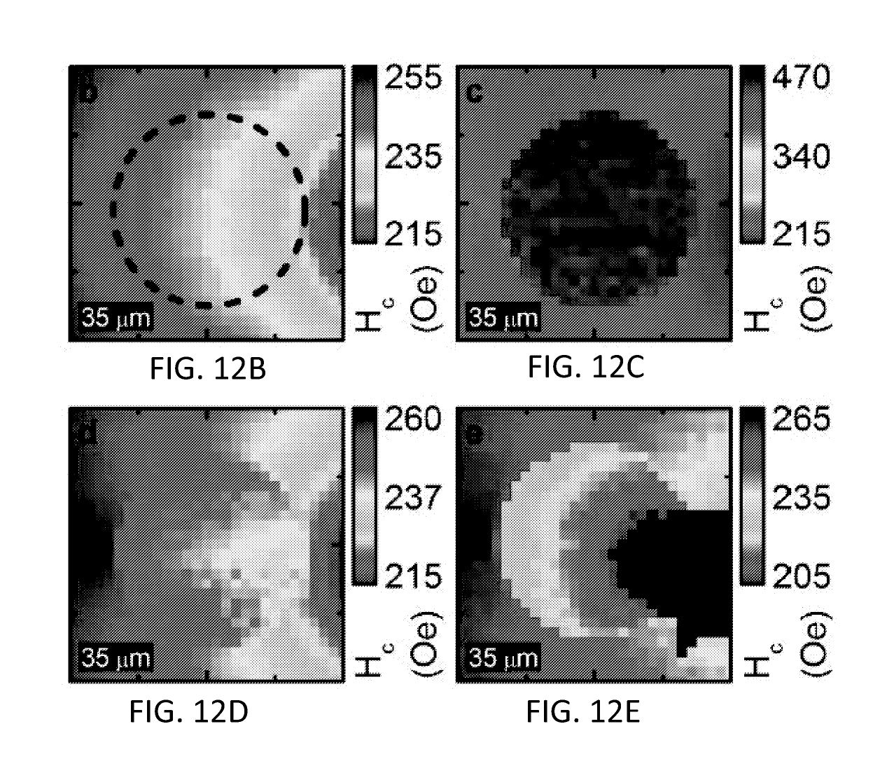

FIGS. 8A-8B show space- and time-resolved images of domain expansion in the example device of FIG. 8B at zero V_{g}, which reveal the origin of the H_{c} enhancement. At each pixel, the magnetization is first saturated, and then a reverse field H=+170 Oe is applied while acquiring a time-resolved MOKE signal transient. Fifty reversal cycles are averaged at each position, from which the average trajectory of the expanding domain is reconstructed. FIGS. 8A-8D show sequences of snapshots of domain expansion at increasing times after field-step application. In the virgin state (FIG. 8A), the domain wall passes unimpeded in the ferromagnetic material layer in the overlap region underneath the gate electrode. In the high-H_{c} state, domain expansion is blocked at the electrode edge, regardless of whether the artificial domain wall nucleation site is outside (FIG. 8B) or inside (FIG. 8C) the overlap region underneath the gate electrode (see also FIGS. 12B-12E).

The domain-wall creep velocity, which depends sensitively on interface anisotropy, is unchanged underneath the electrode in the high-H_{c} state (Supplementary FIG. S2). Accordingly, the irreversible changes that block domain wall propagation after voltage application occur only at the electrode perimeter. This indicates the formation of either a potential barrier or a potential well depending on whether the local anisotropy energy is enhanced or reduced by voltage application. The panels in FIG. 8D show a continuation of the sequence in FIG. 8C after subsequent application of a negative field step. If the electrode perimeter acts as a potential barrier, the domain within the electrode should collapse inward as the domain wall retreats from the electrode edge. However, the domain wall remains pinned at the electrode perimeter. Reversal inside the electrode instead proceeds by nucleation of a reversed domain underneath the tungsten probe tip. The results of FIGS. 8A-8D demonstrate that the electrode perimeter acts as a strong domain wall trap.

The non-volatility of this effect and its localization at the electrode perimeter, where the electrostatic field is weaker than it is at the interior, indicate that electric-field-induced electron accumulation/depletion may not be responsible. Rather, the timescale of trap creation (seconds), together with the unprecedentedly strong influence on domain wall propagation, suggest an ionic rather than electronic origin. Rare-earth gadolinium-based oxides can be configured as solid-state ionic conductors based on exploiting its high O²⁻ vacancy mobility. For example, rare-earth gadolinium-based oxides can be configured as memristive switching devices and oxygen exchange in solid oxide fuel cells.

Since the perpendicular magnetic anisotropy in the Co/metal oxide bilayers is highly sensitive to interfacial oxygen coordination, the O²⁻ vacancy transport in the GdOx permits voltage-controlled O²⁻ accumulation or depletion near the Co/GdOx interface, which consequently alters the local magnetic energy landscape. Negative V_{g} can drive O²⁻ towards the Co/GdOx interface, and over-oxidation of the Co would decrease both PMA and the saturation magnetization. The resulting decrease in magnetic energy density confined to a very short length scale near the electrode edge could produce a domain wall trap consistent with these measurement results.

The gate electrode edge corresponds to the triple phase boundary (TPB) where O₂ gas, O²⁻ ion-conducting and electron-conducting phases meet and electrochemical reactions occur most efficiently. Since domain wall traps are generated near the TPB, the open oxide edge in the example device of FIG. 8B can provide the high-diffusivity path for O²⁻ ions to the Co/GdOx interface. Bulk diffusion can be much slower than surface diffusion, so the timescale for these effects may be correspondingly longer for the example device of FIG. 8A, consistent with the lack of irreversibility at low voltage observed in measurements of that sample. This is supported by measurement results indicating oxygen evolution near breakdown at large positive V_{g}, as well as photo-induced enhancement.

FIGS. 9A-9G show examples of control of domain wall propagation in magnetic nanostrip conduits. FIG. 9A shows schematics of a non-limiting example device where the ferromagnetic material layer includes a nanostructure having a longitudinal conformation, such as but not limited to a nanostrip or a nanoconduit. FIG. 9A shows a 30-μm-long and 500-nm-wide Ta/Pt/Co/GdOx nanostructure conduit with orthogonal Cu contact lines at each end (for domain wall initialization by current pulse I_{nuc}) and a 5-μm-wide GdOx/Ta/Au gate electrode at the center of the wire. The cone represents a focused MOKE laser probe. FIGS. 9B-9G show example results of measurements of the domain wall propagation field along a central region of the nanostructure for the example device in the virgin state (FIGS. 9B and 9E), after application of V_{g}=−5 V for 60 s (FIGS. 9C and 9F), and after application of V_{g}=+6 V for 120 s (FIGS. 9D and 9G) with domain wall initialization from the right end (FIGS. 9B through 9D) or left end (FIGS. 9E through 9G) of the nanowire conduit. The measurements are performed at a gate voltage V_{g}=0 V.

The nanostrip conduit devices are fabricated using electron-beam lithography and liftoff, and are prepared in three steps. The nanostrip is patterned first, followed by the Cu nucleation lines, and finally the gate electrodes are deposited. Domain walls are nucleated in these devices by the Oersted field from a 25-ns-long current pulse (about 100 mA) injected through the Cu line.

The measurement results in FIG. 9B-9G show that voltage-gated domain wall traps can effectively be used to control domain wall propagation in magnetic nanostructures having a longitudinal conformation. The non-limiting example device of FIG. 9A is a 500-nm-wide, 30-μm-long Ta(4 nm)/Pt(3 nm)/Co(0.9 nm)/GdOx(3 nm) nanostrip (or nanoconduit) that is fabricated with a 5-μm-wide GdOx(30 nm)/Ta(2 nm)/Au(12 nm) gate electrode disposed at a portion of its central region. The domain wall nucleation lines at are disposed at either end of the nanostrip (see FIG. 9A). FIGS. 9B-9G show measurement results of the domain wall propagation field Hₚᵣₒₚ versus position, measured by first nucleating a domain wall at one end of the nanostrip with a current pulse through the Cu line, and then sweeping H while detecting domain wall propagation using MOKE. In the virgin state (FIGS. 9B and 9E), domain walls propagate freely underneath the gate. After applying V_{g}=−5 V for 60 s and then setting V, to zero, Hₚᵣₒₚ for leftward-propagating domain walls (FIG. 9C) exhibits a large step at each edge of the gate, whereas for rightward-propagating domain walls (FIG. 9F) there is a single step at the left side of the gate. These results indicate the presence of localized domain wall traps at the right and left edges of the gate, with pinning strengths of about 300 Oe and about 400 Oe, respectively. As seen in FIGS. 9D and 9G, the traps can be removed subsequently by application of a positive gate voltage.

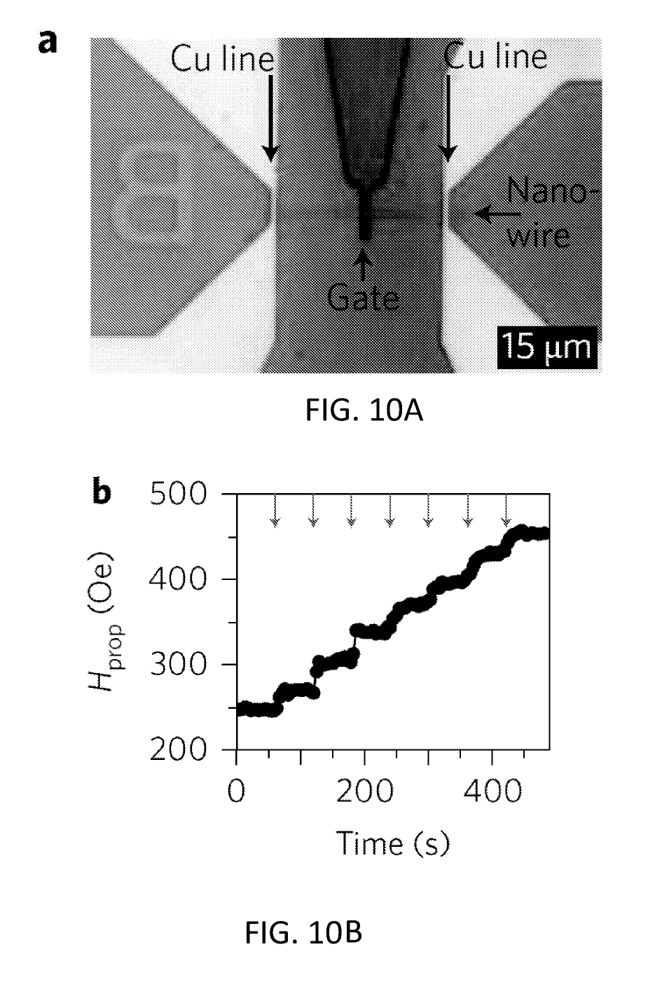

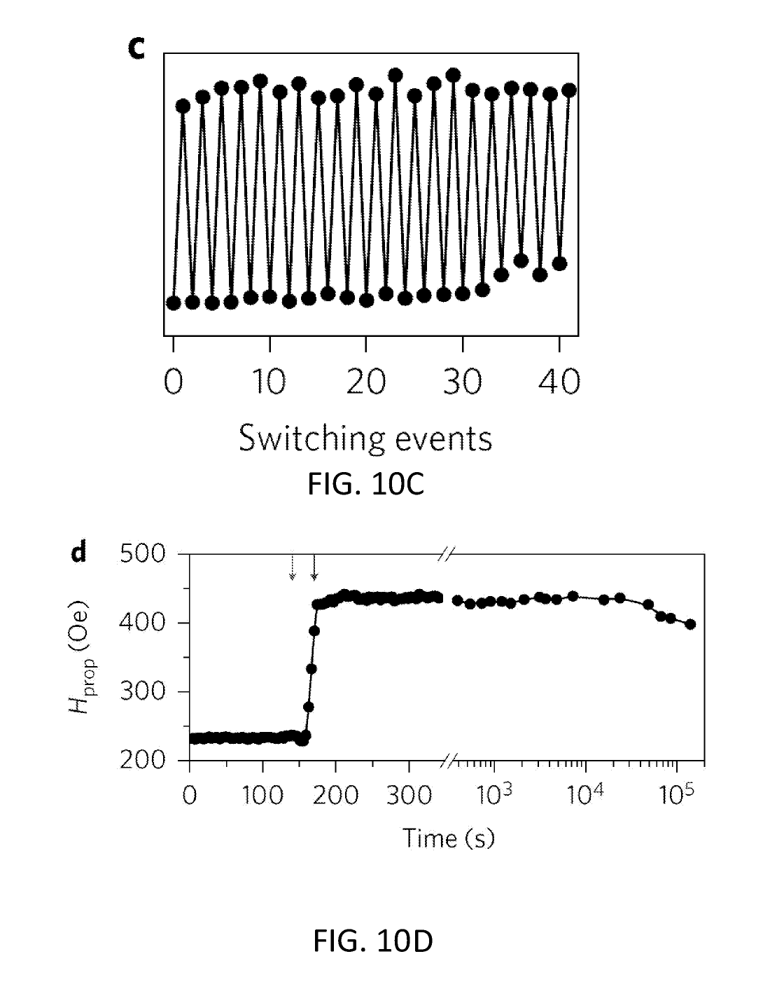

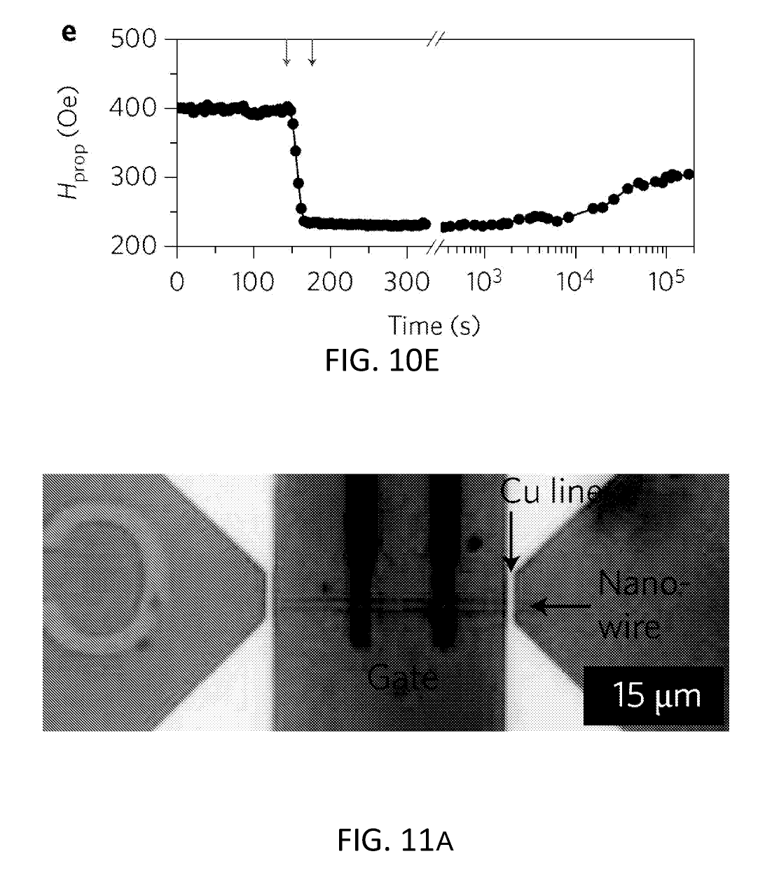

FIGS. 10A-10E shows example measurement results of the properties of domain wall traps in nanostrip conduits. FIG. 10A shows an example optical micrograph showing a Ta/Pt/Co/GdOx nanowire conduit with Cu lines and a GdOx/Ta/Au gate with a reduced width of 800 nm. FIG. 10B shows a plot of example measurement results indicating a stepwise increase in domain wall trap pinning strength following application of 5 s duration voltage pulses of V_{g}=−3 V (indicated by arrows). FIG. 10C shows a plot of example measurement results from twenty (20) switching cycles of domain wall trap pinning strength between about 250 Oe and about 450 Oe. FIGS. 10D and 10E show plots of example measurement results of the first switching cycle of a virgin device, showing retention of pinning strength over 48 h after application of V_{g}=−5 V for 30 s (FIG. 10D) and then after V_{g}=+5 V for 30 s (FIG. 10D). In each of FIGS. 10D and 10E, the left arrow indicates the time point of time of bias application, and the right arrow indicates the time point of time of bias removal.

Using an example device with a reduced the gate electrode width of about 800 nm (shown in FIG. 10A), directional asymmetry in Hₚᵣₒₚ is greatly reduced. This indicates that that the domain wall traps begin to overlap at this length scale. The measurement results in FIG. 10B show that Hₚᵣₒₚ can be programmatically set to any desired level up to at least about 650 Oe (the limit of the electromagnet used to make the measurements) by controlling the integrated voltage dwell time. At H=650 Oe, the magnetic domain walls travel at about 20 m s⁻¹ (see FIGS. 9A-9G). Even at this speed, the domain walls came to a standstill upon entering the voltage-controlled trap that is generated at the gate electrode. In FIG. 10C, Hₚᵣₒₚ is repeatedly cycled between about 250 Oe and about 450 Oe to demonstrate the robustness of the switching mechanism. FIGS. 10D and 10 E show that, once set, Hₚᵣₒₚ remains stable at zero bias for more than 24 hours.

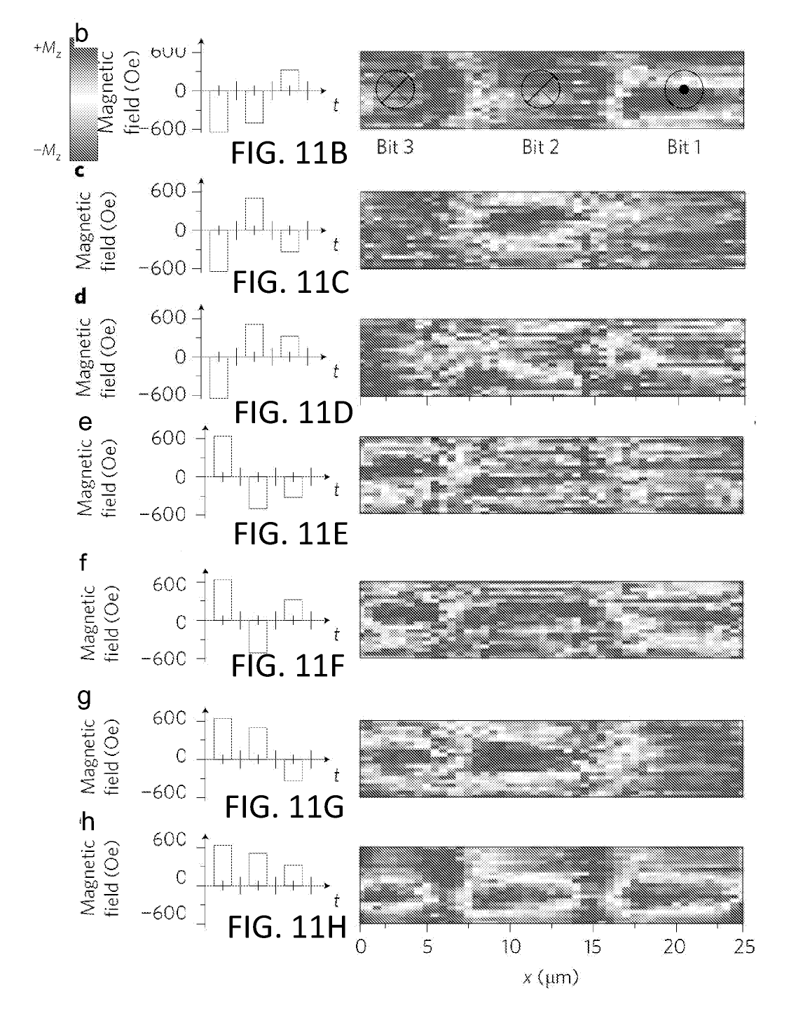

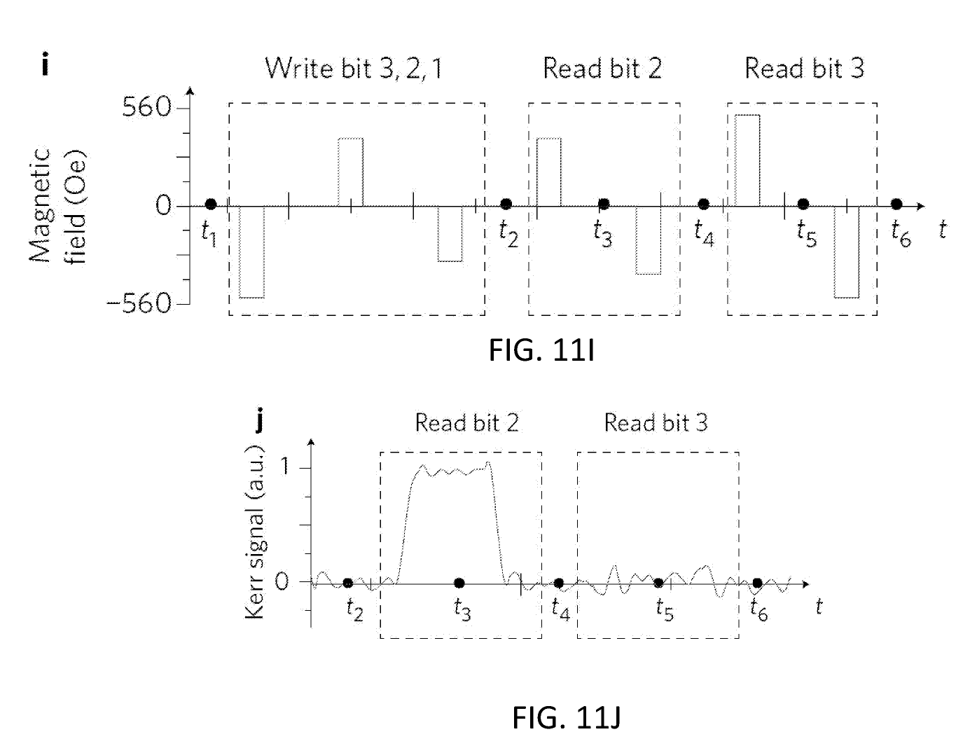

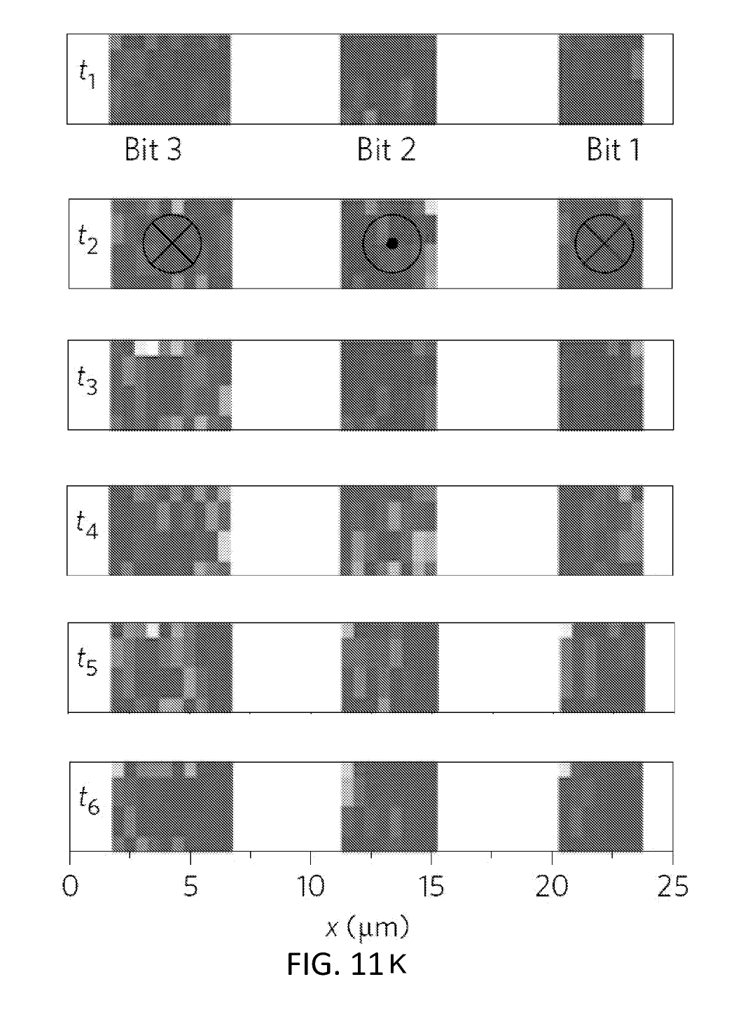

FIGS. 11A-11K show an example device according to the principles herein that can be configured as a n-bit non-volatile memory cell. The example device operates as a domain wall trap-based three-bit register.

FIG. 11A shows an example optical micrograph, showing the example three-bit register device that includes a Ta/Pt/Co/GdOx nanostrip conduit, a Cu contact line coupled to an end of the nanostrip conduit, and two 800-nm-wide GdOx/Ta/Au gate electrodes (each coupled to differing portions of the central region of the nanostrip conduit). FIGS. 11B-11H show example magnetic field pulse sequences (2 ms pulse duration) and Kerr images of the example nanostrip register in the corresponding three-bit state. FIG. 11I shows an example magnetic field pulse sequence (2 ms pulse duration) to write and subsequently read out the three-bit register. FIG. 11J shows an example Kerr signal during readout of the second and third bit. FIG. 11K shows example Kerr images of the nanostrip device at different times t₁-t₆ during the write and readout process. The symbols in the Kerr images of FIGS. 11B and 11K indicate the magnetization direction of individual bits, and the white area in FIG. 11K corresponds to the area of the nanowire conduit obstructed by the gates and Cu lines.

FIG. 11A shows the example micrograph of a three-bit register, with each bit separated by a gate electrode. The domain walls are nucleated using the Cu nucleation line to the right, and the right and left domain wall traps (generated using voltage-control of the gate electrodes) are set to pinning strengths of about 450 Oe and about 550 Oe, respectively. Three field pulses |H|=635 Oe, 505 Oe and 325 Oe are used to write the three bits, with the pulse polarity determining the polarity of the corresponding bit. Field pulse sequences and MOKE maps for all possible domain states are shown in FIGS. 11B-11H, where the down-saturated state is used as a reference to extract the differential MOKE signal.

A non-limiting example n-bit non-volatile memory cell is demonstrated based on n−1 gate electrodes programmed as a cascaded sequence of domain wall traps with successively increasing pinning strength. A bit sequence can be written using a sequence of nmagnetic field pulses applied to the example device of FIG. 11A, each subsequent pulse having successively decreasing amplitude. To write a bit pattern, a new domain wall is initialized with the injection Cu line before each global magnetic field pulse. The magnetic field pulse amplitudes are such that the mth pulse drives the initialized domain wall past the first m−1 domain wall traps but not past the mth trap.

A complementary field pulse sequence is used to read out the bits. In this non-limiting example, readout is performed using MOKE, with the laser spot placed on the first bit. In another example, the readout can be done electrically using, as a non-limiting example, a magnetic tunnel junction coupled to the example device. For the readout process, bit 1 is read and then set to a reference state. Subsequent bits can be read out in sequence by applying read and reset field pulses of equal amplitude, but opposite polarity for each bit. To read the mth bit, the magnetic field pulse amplitude is set to be between the pinning strengths of the (m−1)th and mth domain wall traps. If the state of the mth bit is different from the reference state, the read pulse sweeps the domain wall from the (m−1)th domain wall trap through the first bit, where it is detected. A reset pulse, accompanied by a domain wall nucleation pulse, can be used to reset all previously read bits to a reference state. Otherwise the read and reset pulses have no effect. A non-limiting example of a readout process for the three-bit register is demonstrated in FIGS. 11I-11K. In these non-limiting examples, the reference state (bit 1) is designated as the magnetization down state.

An example system including an array of such example devices could be driven by a single global field source, with any particular nanostrip register addressed as described. Some or all of the other registers can be placed in an inactive state by setting domain wall traps to a high pinning state. These example results demonstrate that voltage-controlled domain wall traps can be used to realize novel devices. Some device applications may require increased switching speed of the voltage-controlled traps compared to the demonstrated example. Such device applications are also within the scope of the principles of the instant disclosure.

The non-limiting measurement results demonstrate that a functionally active gate dielectric allows the creation of voltage-controlled domain wall traps that are non-volatile, programmable and switchable. The observed effects are explained in terms of enhanced ionic mobility in the gate oxide, which permits voltage-controlled changes to interfacial ionic coordination with a consequent modification of interfacial magnetic anisotropy. The capability to localize the voltage-controlled change to a narrow region at the electrode edge leads to sharp voltage-controlled magnetic potential wells with unprecedented pinning strength. The example devices can be configured to provide the voltage-induced effects over timescales ranging from short timescales to relatively long timescales. It is observed that ionic transport can occur at the nanosecond timescale, similarly to memnristive switching devices. Optimization of the gate oxide materials and structure based on design principles used for solid-state ionic devices can permit fast voltage-induced changes to the ferromagnetic material-dielectric oxide material interface, and thereby facilitate rapid switching of magnetic properties. The merger of magnetic and solid-state ionic materials represents a novel class of functional materials that offer an alternative to traditional magnetoelectric composites based on complex dielectric oxides. By replacing ferroelectric or piezoelectric materials with simple oxide dielectrics according to the principles described herein, the magneto-ionic devices herein could provide high-performance magnetoelectric devices using fabrication conditions compatible with complementary metal-oxide semiconductor (CMOS) processing.

In another non-limiting example, the influence of a gate voltage on domain wall (DW) propagation is investigated using the technique described schematically in FIG. 12A. The example device is based on a Pt/Co/GdOx structure (see also the example device of FIG. 8B). FIG. 12A shows the BeCu microprobe for voltage application (1), W microprobe to create artificial DW nucleation site (2) and focused MOKE laser probe to locally measure hysteresis loops in order to map out (x,y) the coercivity H_{c}. The white arrows on the ferromagnetic material layer illustrate local orientation of magnetization vector during expansion of domain from artificial nucleation site. A stiff W microprobe is used to create an artificial domain nucleation site about 100 μm from the center of a gate electrode. A second mechanically-compliant BeCu probe tip is used to gently contact the electrode and apply a gate voltage V_{g}. Hysteresis loops are measured locally via the polar magneto-optical Kerr effect (MOKE) using a ˜3 μm diameter laser spot positioned by a high-resolution scanning stage. Here, the coercivity H_{c} is determined by the propagation field necessary to drive the domain expansion via the domain wall motion.

FIGS. 12B-12E show example maps of H_{c} around gate electrode on the example device of FIG. 12A with the device in a virgin state (FIG. 12B), after V_{g}=−6 V for 180 s (FIGS. 12C and 12E) and after V_{g}=+6 V for 300 s (FIG. 12D). Artificial nucleation site is located to the right of the imaged region (FIGS. 12B-12D) or inside the gate electrode area (FIG. 12E). Measurements are performed at V_{g}=0 V. The example plot of FIG. 12C is shown at a different scale than FIGS. 12B, 12D and 12E. The dashed black line in FIG. 12B indicates the perimeter of the gate electrode.

The example plots of FIGS. 12B-12 E show that H_{c} increases monotonically and continuously with distance from the artificial nucleation site located to the right of the imaged region (see FIG. 12B), as expected for a circularly-expanding domain. H_{c} at the gate electrode center is about 230 Oe. After negative Vg application (FIG. 12C), H_{c} increases abruptly at the electrode perimeter and is uniformly enhanced to about 460 Oe across the gate electrode area. After positive Vg application (FIG. 12D) H_{c} returns to within a few per cent of its initial value, with only a small stepwise increase visible at the electrode edge. Prior to acquiring the data in FIG. 12E, the electrode is switched back to a high-coercivity state with H_{c}, ˜460 Oe. The W microprobe tip is used to generate an artificial nucleation site inside the electrode and H_{c} is again locally mapped. Here, H_{c} is lower inside the electrode than outside, and a clear step is again observed at the perimeter. In this case the step is less than in FIG. 12C because of the reduced nucleation threshold at the first W probe landing site to the right of the electrode. A comparison of FIGS. 12AC and 12E shows that the voltage-induced enhancement in H_{c} is due to blocking of the expanding domain wall at the electrode edge.

A comparison is made of domain wall velocity inside and outside of gate electrode with the domain wall trap. Voltage induced effects on domain wall velocity are investigated in the example device of FIG. 12A by using polar MOKE. A 25 μm diameter blunt W microprobe is used to create an artificial DW nucleation site while a 15 μm diameter BeCu probe tip is used to apply a gate voltage Vg to the gate electrode (see FIG. 12A).

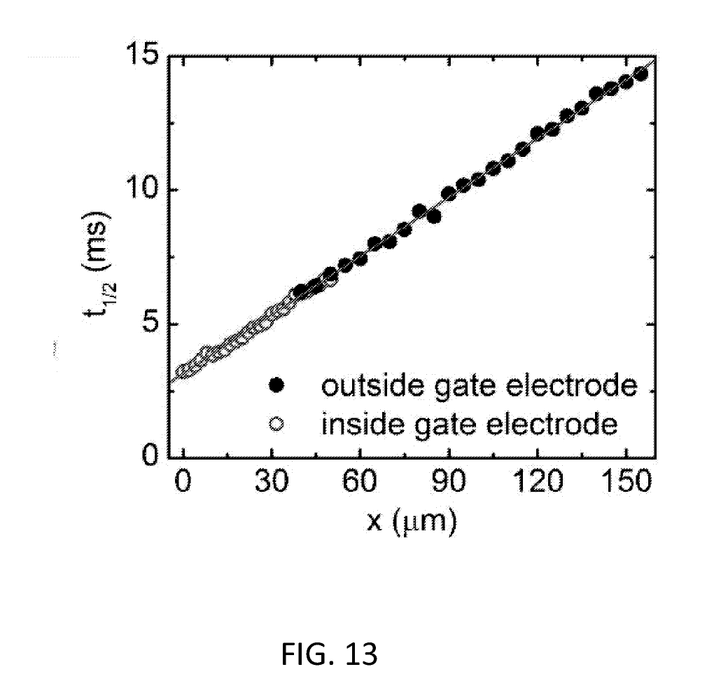

FIG. 13 shows example measurement results of mean magnetization reversal time t_{1/2} as a function of position for the example device of FIG. 12A, extracted from MOKE transients measured at H=170 Oe along a radial line from the artificial nucleation site, after setting DW trap by applying Vg=−6 V for t=180 s. The nucleation site is located outside or inside the gate electrode to measure t_{1/2} versus position outside or inside of the electrode area, respectively. The line through the points is a linear fit to data. The x position of the measurements has been shifted for clarity.

After initially saturating the film magnetization, a reversed perpendicular magnetic field step H is applied using an electromagnet with a ˜300 μs rise-time. The driving field nucleates a reversed domain underneath the W probe tip, which then expands radially across the film. Magnetization reversal is detected via the polar MOKE signal using a ˜3 μm diameter focused laser spot positioned by a high-resolution scanning stage. Time-resolved MOKE transients, corresponding to the averaged signal acquired from 50 reversal cycles, represent the integrated probability distribution of switching times at a given distance from the artificial nucleation site. The mean reversal time (t_{1/2}) is defined as the time at which the probability of magnetization switching is about 50%. By acquiring time-resolved MOKE signal transients along a line extending radially from the artificial nucleation site, the domain wall velocity can be determined from a linear fit of t_{1/2} versus position.

As described herein, after application of a gate voltage Vg=−6 V for t=180 s to the example device on FIG. 12A, the expanding domain is blocked and the domain wall comes to a complete standstill at the electrode edge. When the artificial nucleation site is located outside of the gate electrode, the reversed domain cannot enter the electrode area. When the nucleation site is inside the gate electrode, the reversed domain cannot expand beyond the electrode.

In order to show that the nonvolatile voltage induced effects can be localized to the electrode edge and not extend across the whole electrode area, the DW velocity is measured inside and outside of the gate electrode, after voltage application. Time-resolved MOKE signal transients are acquired along a line extending radially from the artificial nucleation site, which is located either outside or inside of the electrode. FIG. 13 shows the mean reversal time t_{1/2} as a function of distance from the nucleation site, for both cases. As expected for DW propagation, t_{1/2} increases linearly with distance from the nucleation site. In fact, t_{1/2} increases with exactly the same slope outside and inside of the electrode, which shows that the DW velocity is the same ˜1.5×10⁻² m/s in both cases. Since the DW creep velocity depends exponentially on an activation energy barrier Ea which in turn depends on the uniaxial anisotropy constant Ku and saturation magnetization Ms, the creep velocity is very sensitive to changes in Ku and Ms. Therefore, these results demonstrate that the gate voltage may not modify the magnetic properties of the Co film underneath the whole electrode area but affects it underneath the electrode edge.

An example of voltage control of domain walls moving at high velocity in nanowire conduits is demonstrated. The following procedure is employed to measure the DW velocity in nanowire conduit samples. A reversed domain is nucleated at the right end of the magnetic nanowire conduit by the Oersted field of a 25 ns-long current pulse I_{nuc} (˜100 mA) injected through a Cu line orthogonal to the magnetic nanowire conduit (see FIG. 10A).

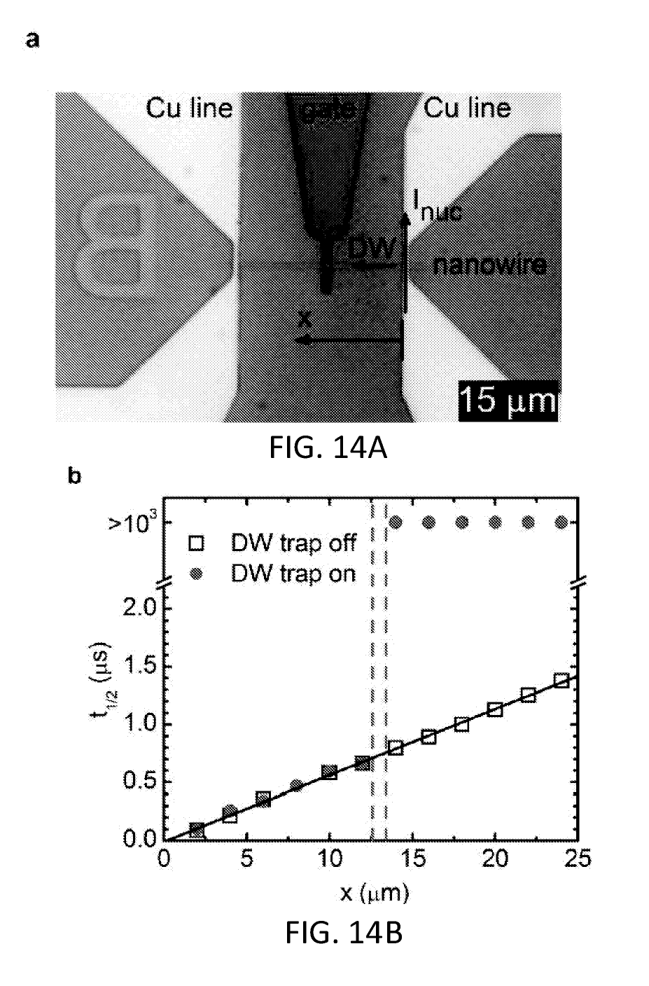

FIG. 14A-14B shown an example of trapping high velocity domain walls. FIG. 14A shows an example device schematic showing a 500 nm wide Pt/Co/GdOx nanostrip conduit with Cu lines at each end for DW initialization and 800 nm wide GdOx/Ta/Au gate to program DW trap. A reversed domain is nucleated at the right end of the magnetic nanowire conduit by the Oersted field of a current pulse I_{nuc} injected through the Cu line on the right. The initialized DW is then driven along the nanowire conduit, away from the nucleation line (in positive x-direction) by a perpendicular magnetic field H. FIG. 14B shows mean reversal time t_{1/2} extracted from time-resolved MOKE transients measured along the nanowire conduit at a driving field H=650 Oe before and after setting DW trap underneath gate electrode. Dashed red line outlines gate electrode position and black line is linear fit to data.

The reversed domain is then expanded by an applied perpendicular magnetic field H, thereby driving an initialized DW along the nanostrip conduit away from the nucleation line as shown in FIG. 14A. Time-resolved MOKE transients, corresponding to the averaged signal acquired from 500 reversal cycles, are measured along the nanostrip in 2 μm steps. Similar to the continuous magnetic film samples, the DW velocity can then be determined from a linear fit of the mean reversal time t_{1/2} versus position.

For a nanostrip conduit device with an 800 nm wide GdOx/Ta/Au gate at its center (see FIG. 14A), MOKE transients are measured along the nanowire conduit before and after a DW trap is initiated underneath the gate electrode by voltage application. In FIG. 14B, it can be seen that without a DW trap underneath the gate, t_{1/2} increases linearly with distance from the nucleation site with the same slope before and after the domain passes underneath the gate electrode. From the slope of t_{1/2} versus position it is determined that the DW is moving at a velocity of ˜20 m/s, which corresponds to the maximum achievable DW velocity with the available H of about 650 Oe.

After a domain wall trap is created and set to a pinning strength of >650 Oe (beyond the maximum available H for the measuring instrument) under a negative bias voltage, the same measurement is repeated. From FIG. 14B it can be seen, that up to the gate electrode the mean reversal times t_{1/2} are unchanged. However, beyond the gate electrode, no magnetization reversal is observed (within the maximum measurement time window of 1 ms). This shows that the voltage-induced DW traps can be utilized to bring to a standstill even domain walls traveling at the high velocities that are relevant for spintronic device applications.

Large, nonvolatile modifications of the switching field H_{c} and the remanence to saturation magnetization ratio Mᵣ/Mₛ can occur in continuous Ta/Pt/Co/GdOx films at high positive gate voltage, close to dielectric break down (BD). Those large modifications are due to motion of mobile ionic species within in the GdOx layer which is expected to occur close to dielectric breakdown. A comparison is made of the high voltage and the low voltage behavior.

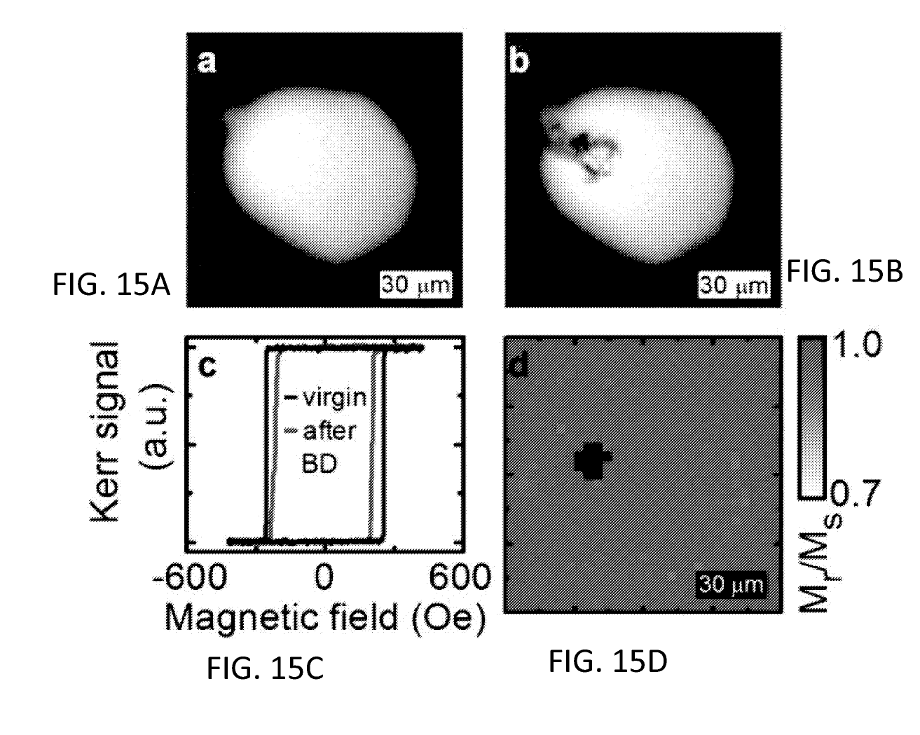

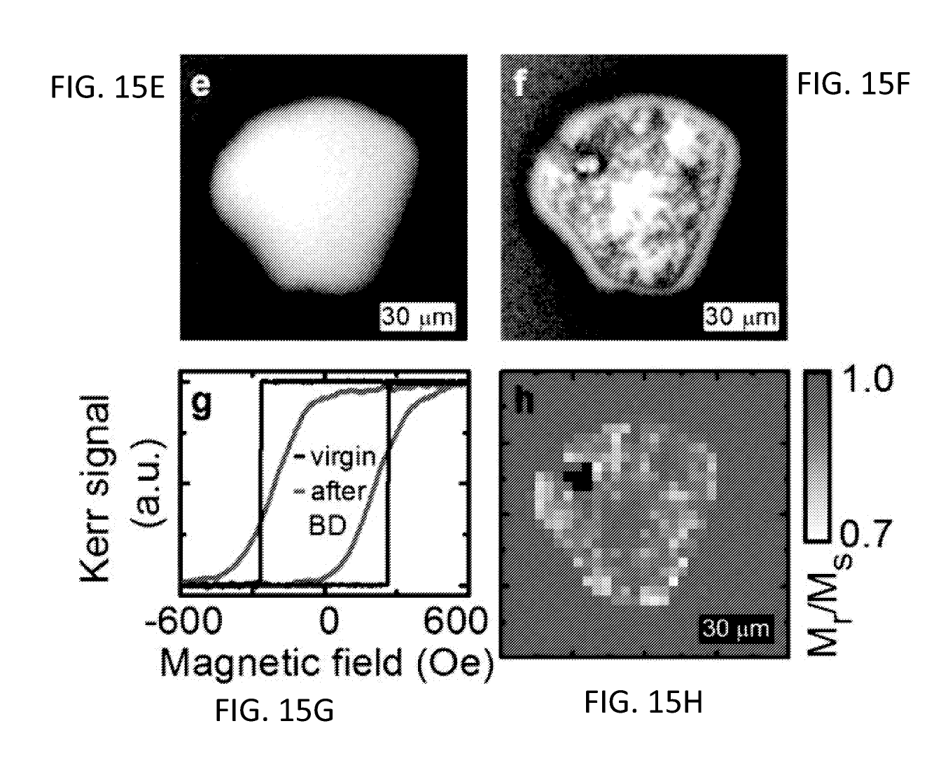

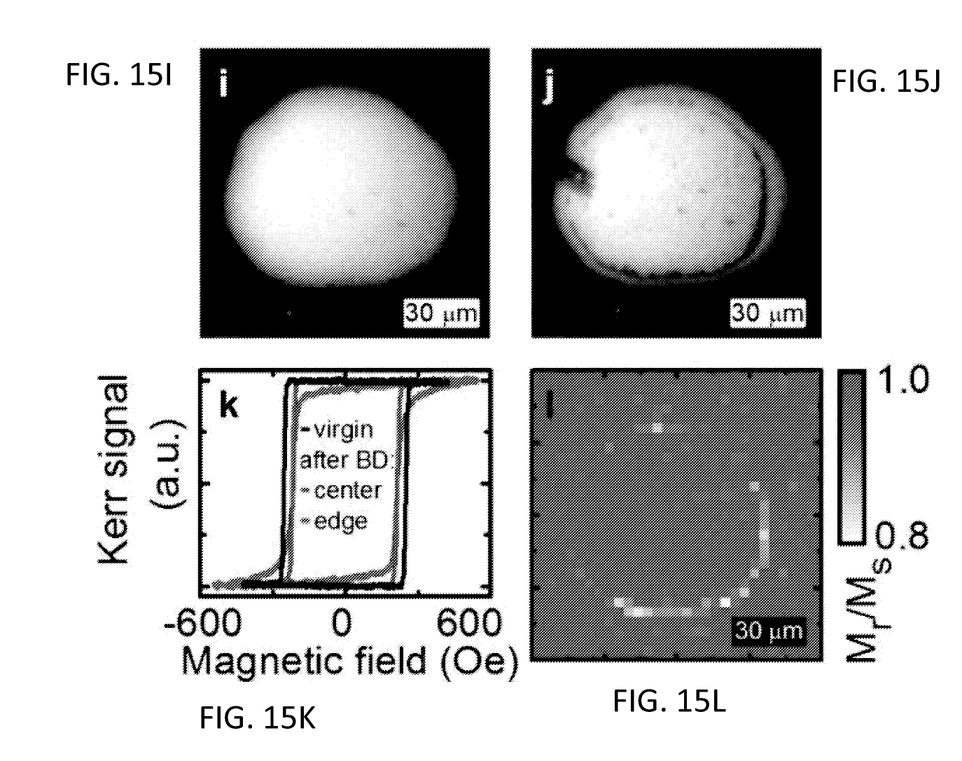

Continuous films of Ta(4 nm)/Pt(3 nm)/Co(0.9 nm)/GdOx(40 nm) are grown (similarly to the example device of FIG. 8A) and on top of them Ta(1 nm)/Au(5 nm) gate electrodes are deposited through a shadow mask. Dielectric BD of the GdOx layer is induced by ramping Vg with a constant rate of ˜3 V/s from 0 V to high positive or negative voltage. In FIGS. 15A-15L, a correlation is made between the change in magnetic properties that occurs under high voltage stress and subsequent dielectric BD with the simultaneously appearing physical degradation of the gate electrode.

FIGS. 15A-15L shows an example of the anisotropy modification and physical electrode degradation in high voltage regime. FIGS. 15A-15D show the behavior under high negative bias stress. FIGS. 15A-15B show the optical micrographs showing Ta/Au gate electrode in virgin state (FIG. 15A) and after dielectric breakdown (BD) (FIG. 15B). FIGS. 15C-15D show hysteresis loops measured in the center of the gate electrode in the virgin state and after BD (FIG. 15C) and Mᵣ/Mₛ map after BD (FIG. 15D) showing same area as seen in FIG. 15B. FIGS. 15E-15H show the behavior under high positive bias stress (fast voltage ramp). FIGS. 15E-15F show optical micrographs showing gate electrode in virgin state (FIG. 15E) and after BD (FIG. 15F). FIGS. 15G-15H show hysteresis loops measured in the center of the gate electrode in virgin state and after BD (FIG. 15G) and a map of Mᵣ/Mₛ (FIG. 15H) showing same area as FIG. 15F. FIGS. 15I-15L shows the behavior under high positive bias stress (slow voltage ramp). FIGS. 15I-15J show optical micrographs showing gate electrode in virgin state (FIG. 15I) and after BD (FIG. 15J). FIGS. 15K-15L show hysteresis loops measured in the center of the gate electrode in the virgin state and in the center and at the edge of the gate electrode after BD (FIG. 15K) and map of Mᵣ/Mₛ (FIG. 15L) showing same area as FIG. 15J. The black points in FIG. 15D and FIG. 15H indicate regions where no polar Kerr signal could be obtained after BD.

For dielectric breakdown (BD) at high negative bias (about −20 V), physical damage of the gate electrode is limited and only occurs in the immediate area (upper left corner) in which the BeCu micro probe is landed to apply the gate voltage (see FIGS. 15A-15B). After BD, no polar Kerr signal could be obtained in the contact area, but in its vicinity, the coercivity H_{c} is significantly reduced which indicates that this area now acts as a nucleation site (see FIGS. 15C-15D).

In contrast, for BD at high positive voltage (about +20 V), physical damage of the gate electrode is widespread and often large parts of the gate electrode are blown off of the GdOx layer (see FIGS. 15E and 15F). After BD, hysteresis loops measured within the damaged area of the electrode show a strong reduction in Mᵣ/Mₛ which indicates a strong reduction in perpendicular magnetic anisotropy (PMA) (see FIG. S4g,h). The strongest modifications of Mᵣ/Mₛ can occur in the areas close to the electrode edge and the effects are somewhat reduced towards the electrode center.

Based on this observation, the voltage ramp rate is reduced to ˜1 V/30 s, which reduced the voltage at which dielectric BD occurred to about 15 V (due to time dependence of dielectric BD, lower voltage ramp rate usually results in lower BD voltage). In this case, physical damage of the gate electrode occurs predominantly at the electrode edge (see FIGS. 15I and 15J) and similarly Mᵣ/Mₛ and therefore PMA is reduced predominantly at the edge of the gate electrode (see FIGS. 15K and 15L).

FIGS. 15A-15L show that the electrode damage exhibits polarity dependence under high bias stress. Moreover it shows a direct correspondence between the area in which electrode damage occurs (i.e. where electrode material is removed) and the area in which the magnetic properties are modified, which suggests a common origin. FIG. 15I-15L show that the underlying process responsible for electrode damage and modification of magnetic properties occurs most efficiently at the electrode perimeter (i.e. the triple phase boundary). Those observations suggest the presence of a mobile species which is either released or incorporated into the GdOx depending on the polarity of the bias voltage.

Under fast voltage ramp to high positive bias, widespread damage is observed across the electrode consistent with O² release and blow-off of electrode material. The low oxygen permeability of Au supports this interpretation. Oxygen gas release from the GdOx and the resulting modification of O²⁻ stoichiometry in the GdOx film can impact PMA, which is consistent with the observed modifications of Mᵣ/Mₛ in the areas in which electrode damage occurred (i.e. electrode material is removed).

In contrast, at high negative bias, oxygen incorporation occurs instead of release, as expected given the absence of wide spread physical damage of the electrode. Since incorporated oxygen moves through the thickness of the GdOx layer before reaching the Co/GdOx interface, modifications of the magnetic properties are likely preempted by break down of the GdOx layer through an electronic avalanche process directly underneath the BeCu probe.

For the continuous GdOx films investigated here, high voltages can be used to overcome the high diffusion resistance of the continuous GdOx film. Such high voltage can result in dielectric BD of the GdOx layer and degradation and damage of the device. The data presented in the manuscript indicate that by engineering the dielectric layer (such as in the example device of FIG. 8B) the diffusion resistance can be reduced and it is possible to achieve similar magneto-ionic effects at much lower voltages, reversibly, reliably and without damage to the device.

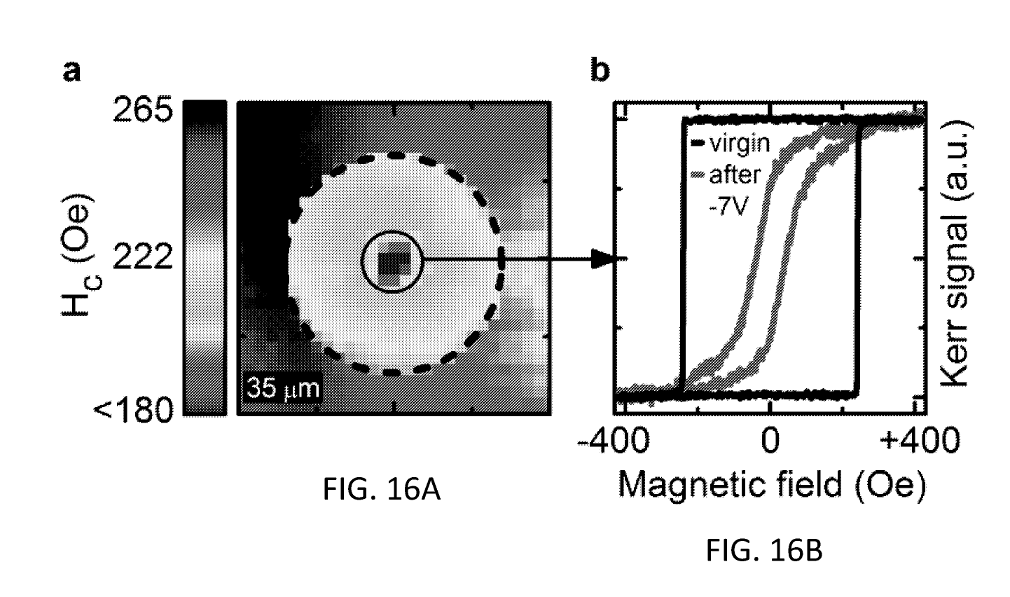

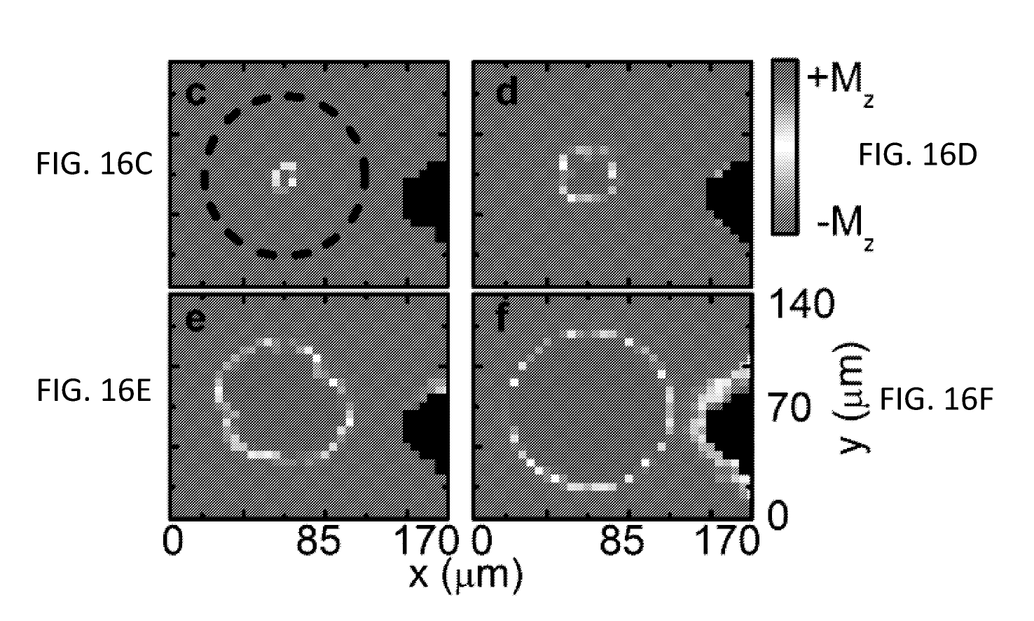

Optically enhanced effects are described. FIGS. 16A-16F shows example voltage effects under local illumination. FIG. 16A show an example map of coercivity H_{c} in the vicinity of gate electrode on the example device of FIG. 8B, measured at V_{g}=0 V after application of Vg=−7 V and simultaneous laser illumination of the electrode center for 180 s. FIG. 16A shows hysteresis loops showing normalized Kerr signal, measured in the area exposed to laser light before and after voltage application. FIG. 16C-16F show polar MOKE maps showing domain expansion from area exposed to laser light with increasing time after application of magnetic field step (H=170 Oe). The scale of the plot in FIG. 16A is cut off at 180 Oe for clarity. The dashed black line in FIGS. 16A and 16C show the perimeter of the gate electrode. The continuous black line in FIG. 16A highlights area exposed to laser light during bias application. The black map area in FIGS. 16C-16F corresponds to W microprobe used to create artificial nucleation site.

For the example device of FIG. 8B, voltage application modifies the magnetic properties of the Co film at the electrode perimeter. However, when part of the gate electrode is illuminated by laser light during bias application, it is observed that the magnetic properties of the Co film are also modified in the electrode area exposed to the laser light (see FIG. 16A).

Here, the 532 nm diode laser used is attenuated to 1 mW and focused to a ˜3 μm diameter spot to locally expose a part of the gate electrode. The temperature rise underneath the laser spot is estimated to be less than about 1° C. As shown in FIGS. 16C-16F, after application of Vg=−7 V for 180 s while simultaneously exposing the electrode center to laser light, the exposed area acts as a nucleation site for a reversed domain, consistent with a local reduction in the DW energy landscape. In fact, the hysteresis loops measured in the exposed area (see FIG. 16B) show a large reduction in switching field from 240 Oe to 40 Oe and in the remnant to saturation magnetization ratio Mᵣ/Mₛ from 1 to 0.54, indicating a strong reduction in PMA. Moreover, it is observed that after bias application and illumination, the MOKE signal is significantly reduced.

The hysteresis loops in FIG. 16B directly show a reduction in PMA under negative gate voltage which confirms our finding that the DW traps at the electrode edge are due to a potential well and not a potential barrier. Indeed, the H_{c} map in FIG. 16A shows that the DW traps at the electrode edge and the nucleation site in the electrode center are simultaneously created at negative bias. The electrode edge and laser exposure both facilitate a local reduction in PMA, however due to its larger size and Gaussian intensity profile the laser spot results in a DW nucleation site whereas the electrode edge results in a DW trap.

Considering the strong PMA of the sample (in-plane saturation field of >10 kOe), the hysteresis loops shown in FIG. 16B indicate a large anisotropy modification consistent with a change in O²⁻ coordination at the Co/GdOx interface. The observed reduction in Kerr signal is consistent with the additional Co oxidation expected under negative bias.

As described herein, optical illumination can assist metal oxidation and promote redox reactions on metal-oxide catalysts. Illumination is also shown to enhance the performance of solid oxide fuel cells, particularly at low operation temperatures, through an increased rate of oxygen incorporation. Optically enhanced diffusivity of ionic defects are observed. Under bias application, laser exposure can facilitate modifications in O²⁻ coordination at the Co/GdOx interface even underneath the electrode interior (i.e. away from the electrode perimeter) and result in the observed anisotropy modifications.

Other non-limiting example applications of systems, devices, methods, and apparatus described herein include in security, military, and industrial applications. The example systems, devices, methods, and apparatus described herein can be implemented in spectroscopic applications as well.

In another non-limiting example, systems, devices, methods, and apparatus described herein can be made low-cost and/or disposable.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments of the invention can be implemented in any of numerous ways. For example, some embodiments may be implemented using hardware, software or a combination thereof. When any aspect of an embodiment is implemented at least in part in software, the software code can be executed on any suitable processor or collection of processors, whether provided in a single computer or distributed among multiple computers.

In this respect, various aspects of the invention may be embodied at least in part as a computer readable storage medium (or multiple computer readable storage media) (e.g., a computer memory, one or more floppy disks, compact disks, optical disks, magnetic tapes, flash memories, circuit configurations in Field Programmable Gate Arrays or other semiconductor devices, or other tangible computer storage medium or non-transitory medium) encoded with one or more programs that, when executed on one or more computers or other processors, perform methods that implement the various embodiments of the technology discussed above. The computer readable medium or media can be transportable, such that the program or programs stored thereon can be loaded onto one or more different computers or other processors to implement various aspects of the present technology as discussed above.

The terms “program” or “software” are used herein in a generic sense to refer to any type of computer code or set of computer-executable instructions that can be employed to program a computer or other processor to implement various aspects of the present technology as discussed above. Additionally, it should be appreciated that according to one aspect of this embodiment, one or more computer programs that when executed perform methods of the present technology need not reside on a single computer or processor, but may be distributed in a modular fashion amongst a number of different computers or processors to implement various aspects of the present technology.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, the technology described herein may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. A device comprising:
a ferromagnetic material layer disposed in an x-y plane;
a gate oxide dielectric layer disposed over the ferromagnetic material layer and having a first lateral dimension in the x-y plane; and
a gate electrode layer disposed over, and in electrical communication with, the gate oxide dielectric material layer and having a second lateral dimension in the x-y plane;
wherein the first lateral dimension of the gate oxide dielectric layer is approximately equal to the second lateral dimension of the gate electrode layer; and
wherein the gate electrode layer, the gate oxide dielectric layer, and the ferromagnetic material layer are configured such that:
a first potential difference applied in a first direction between the gate electrode layer and the ferromagnetic material layer generates a domain wall pinning site at a region of the ferromagnetic material layer; and
a second potential difference applied in a second direction, opposite to the first direction, between the gate electrode layer and the ferromagnetic material layer substantially eliminates the domain wall pinning site.

2. The device of claim 1, further comprising an intermediate oxide dielectric material layer disposed between the ferromagnetic material layer and the gate oxide dielectric layer, wherein the intermediate oxide dielectric material layer has a third lateral dimension in the x-y plane that is greater than the first lateral dimension of the gate oxide dielectric layer, and wherein the gate oxide dielectric layer has a greater thickness in a z-direction than the intermediate oxide dielectric material layer.

3. The device of claim 2, wherein the intermediate oxide dielectric material layer is formed from a different material from that of the gate oxide dielectric layer.

4. The device of claim 1, wherein the gate oxide dielectric layer is formed from an oxide, an oxynitride, or a silicate of a transition metal, or of a rare earth metal.

5. The device of claim 1, wherein the gate oxide dielectric layer is formed from an oxide, oxynitride, or silicate of Gd, Ta, Zr, or Hf.

6. The device of claim 1, wherein the gate oxide dielectric layer comprises at least one of gadolinium, hafnium, terbium, zirconium, yttrium, tantalum, titanium, and aluminum.

7. The device of claim 1, wherein the ferromagnetic material layer is disposed over at least one of: an electrically conductive layer, at least one additional ferromagnetic material layer, at least one additional oxide dielectric layer, a tunnel barrier layer, and an integrated circuit stack.

8. The device of claim 1, wherein the ferromagnetic material layer has a longitudinal conformation.

9. The device of claim 8, wherein the ferromagnetic material layer comprises at least one nanostrip.

10. The device of claim 9, wherein the at least one nanostrip has a first end, a second end, and a central region, wherein the first lateral dimension of the gate oxide dielectric layer is less than a length of the at least one nanostrip, and wherein the gate oxide dielectric layer is disposed over a portion of the central region of the at least one nanostrip.

11. The device of claim 1, further comprising a domain wall nucleating component to nucleate at least one domain wall at a region of the ferromagnetic material layer that is not in an overlap region between the gate electrode layer and the ferromagnetic material layer.

12. The device of claim 1, wherein the ferromagnetic material layer is disposed over an electrically conductive material layer and/or a magnetic tunnel junction.

13. The device of claim 1, wherein the ferromagnetic material comprises iron, nickel, cobalt, samarium, dysprosium, yttrium, chromium, or an alloy of at least one of iron, nickel, cobalt, and samarium alloyed with at least one of boron, carbon, copper, hafnium, palladium, platinum, rhenium, rhodium, or ruthenium.

14. The device of claim 1, wherein the device is a spintronic device, a magnetic recording device, a memristor, a non-volatile memory device, a magnetoresistive random-access memory device, a voltage-controlled magnetic memory, an electrically controllable catalysis device, a voltage controlled optical switch, a flash drive, an electrically erasable programmable read-only memory, a solid-state drive, a dynamic random-access memory, or a static random-access memory.

15. The device of claim 1, wherein the ferromagnetic material layer has a fourth lateral dimension in the x-y plane that is greater than the first lateral dimension and the second lateral dimension.

16. A device comprising:
a ferromagnetic material layer disposed in an x-y plane;
a gate oxide dielectric layer disposed over the ferromagnetic material layer and having a first lateral dimension in the x-y plane; and
a gate electrode layer disposed over, and in electrical communication with, the gate oxide dielectric material layer and having a second lateral dimension in the x-y plane;
wherein the second lateral dimension of the gate electrode layer is smaller than the first lateral dimension of the gate oxide dielectric layer; and
wherein the gate electrode layer, the gate oxide dielectric layer, and the ferromagnetic material layer are configured such that a first potential difference applied in a first direction between the gate electrode layer and the ferromagnetic material layer generates a change in the magnetic anisotropy at a portion of the ferromagnetic material layer proximate to the portion of the gate oxide dielectric layer that is proximate to the gate electrode layer.

17. The device of claim 16, wherein the gate oxide dielectric layer is formed from an oxide, an oxynitride, or a silicate of a transition metal or of a rare earth metal.

18. The device of claim 16, wherein the gate oxide dielectric layer is formed from an oxide, oxynitride, or silicate of Gd, Ta, Zr, or Hf.

19. The device of claim 16, wherein the ferromagnetic material layer has a longitudinal conformation.

20. The device of claim 19, wherein the ferromagnetic material layer comprises at least one nanostrip.

21. The device of claim 20, wherein the at least one nanostrip has a first end, a second end, and a central region, wherein the first lateral dimension of the gate oxide dielectric layer is less than a length of the at least one nanostrip, and wherein the gate oxide dielectric layer is disposed over a portion of the central region of the at least one nanostrip.

22. The device of claim 16, wherein the ferromagnetic material layer is disposed over at least one of: an electrically conductive layer, at least one additional ferromagnetic material layer, at least one additional oxide dielectric layer, a tunnel barrier layer, and an integrated circuit.

23. The device of claim 16, further comprising an intermediate oxide dielectric material layer disposed between the ferromagnetic material layer and the gate oxide dielectric layer, and having a third lateral dimension in the x-y plane, wherein the third lateral dimension is greater than the first lateral dimension and the second lateral dimension.

24. The device of claim 23, wherein the gate oxide dielectric layer has a greater thickness in a z-direction than the intermediate oxide dielectric material layer.

25. The device of claim 23, wherein the intermediate oxide dielectric material layer is formed from a different material from that of the gate oxide dielectric layer.

26. The device of claim 23, wherein the ferromagnetic material layer has a fourth lateral dimension in the x-y plane, and wherein the first lateral dimension is approximately equal to the fourth lateral dimension.

27. The device of claim 23, wherein the gate oxide dielectric layer and/or the intermediate oxide dielectric material layer comprises at least one of gadolinium, hafnium, terbium, zirconium, yttrium, tantalum, titanium, and aluminum.

28. The device of claim 16, wherein the ferromagnetic material comprises iron, nickel, cobalt, samarium, dysprosium, yttrium, chromium, or an alloy of at least one of iron, nickel, cobalt, and samarium alloyed with at least one of boron, carbon, copper, hafnium, palladium, platinum, rhenium, rhodium, or ruthenium.

29. The device of claim 16, wherein the device is a spintronic device, a magnetic recording device, a memristor, a non-volatile memory device, a magnetoresistive random-access memory device, a voltage-controlled magnetic memory, an electrically controllable catalysis device, a voltage controlled optical switch, a flash drive, an electrically erasable programmable read-only memory, a solid-state drive, a dynamic random-access memory, or a static random-access memory.

30. The device of claim 16, wherein the change in the magnetic anisotropy of the ferromagnetic material layer is an increase or reduction of a perpendicular magnetic anisotropy.

31. The device of claim 16, wherein the change in the magnetic anisotropy of the ferromagnetic material layer is an increase or reduction of an in-plane magnetic anisotropy.

32. The device of claim 16, wherein the change in the magnetic anisotropy of the ferromagnetic material layer is a change from a perpendicular magnetic anisotropy to an in-plane magnetic anisotropy.

33. A device comprising:
a first ferromagnetic material layer disposed in an x-y plane;
a tunnel barrier layer disposed over the first ferromagnetic material layer,
a second ferromagnetic material layer disposed over the first ferromagnetic material layer;
a gate oxide dielectric layer disposed over the second ferromagnetic material layer, the gate oxide dielectric layer having high oxide ion mobility; and
a gate electrode layer disposed over, and in electrical communication with, the gate oxide dielectric material layer,
wherein the second ferromagnetic material layer is configured to reversibly uptake an amount of the oxide ions; and
wherein the gate electrode layer, the gate oxide dielectric layer, and the second ferromagnetic material layer are configured such that a first potential difference applied in a first direction generates a change in the proportionate amount of the oxide ions in a portion of the target layer, thereby causing a change in a magnetic anisotropy of the second ferromagnetic material layer.

34. The device of claim 33, further comprising an intermediate oxide dielectric material layer disposed between the second ferromagnetic material layer and the gate oxide dielectric layer.

35. A method for programming information to a device, the method comprising:
nucleating a magnetic domain wall at a region of a ferromagnetic material layer of a device, the device comprising:
the ferromagnetic material layer disposed in an x-y plane, and having a first lateral dimension in the x-y plane;
a gate oxide dielectric layer disposed over the ferromagnetic material layer and having a second lateral dimension in the x-y plane; and
a gate electrode layer disposed over, and in electrical communication with, the gate oxide dielectric material layer and having a third lateral dimension in the x-y plane;
wherein the first lateral dimension are greater than the second lateral dimension and the third lateral dimension;
applying a first magnetic field having a first polarity to the device; and
applying a potential difference between the gate electrode layer and the ferromagnetic material layer;
wherein the gate electrode layer, the gate oxide dielectric layer, and the ferromagnetic material layer are configured such that:
the potential difference applied in a first direction between the gate electrode layer and the ferromagnetic material layer generates a domain wall pinning site at a region of the ferromagnetic material layer; and
the potential difference applied in a second direction, opposite to the first direction, between the gate electrode layer and the ferromagnetic material layer substantially eliminates the domain wall pinning site.

36. The method of claim 35, further comprising applying a second magnetic field to the device, the second magnetic field having a smaller amplitude than the first magnetic field pulse.

37. The method of claim 36, wherein the second magnetic field pulse has a second polarity that is opposite to the first polarity of the first magnetic field.

38. The method of claim 35, wherein the first polarity of the first magnetic field programs a first type of information to the device, and wherein the second polarity of the second magnetic field programs a second type of information to the device that is different from the first type of information.

39. The method of claim 38, wherein the first type of information is a first magnetization direction of a portion of the device, and wherein the second type of information is a second magnetization direction of the portion of the device that is different from the first magnetization direction.

40. The method of claim 39, wherein the nucleating the magnetic domain wall comprises applying a mechanical stress to a region of the ferromagnetic material layer.
